(19) United States
(12) Patent Application Publication
(10) Pub. No.: US 2026/0198384 A1
(43) Pub. Date: Jul. 9, 2026

(54) A WAFER-LEVEL PACKAGE AND A METHOD FOR FORMING THE WAFER-LEVEL PACKAGE

(71) Applicant: Agency for Science, Technology and Research, Singapore (SG)

(72) Inventors: Sajay BHUVANENDRAN NAIR GOURIKUTTY, Singapore (SG); Suryanarayana Shivakumar BHATTACHARYA, Singapore (SG); Wen Wei SEIT, Singapore (SG); Teck Guan LIM, Singapore (SG); Rathin MANDAL, Singapore (SG); Mihai Dragos ROTARU, Singapore (SG); Srinivasa Rao VEMPATI, Singapore (SG)

(21) Appl. No.: 19/133,844

(22) PCT Filed: Nov. 29, 2023
(86) PCT No.: PCT/SG2023/050794

§ 371 Date: May 29, 2025

(30) Foreign Application Priority Data
Nov. 30, 2022 (SG) 10202260261S

(51) Int. Cl. H10W 90/10; H10W 70/65; H10W 72/20; H10W 74/01; H10W 74/10

(52) U.S. Cl. CPC H10W 90/10; H10W 70/6565; H10W 74/01; H10W 74/141; H10W 72/20

(57) ABSTRACT

A wafer-level package is described. In an embodiment, the wafer-level package (100) comprises: a substrate (102) having electrically conductive interconnects embedded within the substrate (102), the substrate (102) having a top substrate surface and a bottom substrate surface opposite to the top substrate surface, the bottom substrate surface being adapted to be provided on a printed circuit board (PCB); a first integrated circuit die (104) having an active surface wherein the first integrated circuit die is provided adjacent to an edge portion of a perimeter of the substrate (102); a mold (108) adapted to hold the first integrated circuit die (104) and the substrate (102) so that the active surface of the first integrated circuit die (104) is in a same plane as the top substrate surface; a first redistribution layer (110) having electrically conductive interconnects embedded within the first redistribution layer (110), the first redistribution layer (110) being formed on the active surface of the first integrated circuit die (104) and the top substrate surface; and a second integrated circuit die (112) provided on the first redistribution layer (110), the second integrated circuit die (112) being electrically connected to the first integrated circuit die (104) via the first redistribution layer (110). Embodiments in relation to a method (200) for forming the wafer-level package are also described.

### TECHNICAL FIELD

The present disclosure relates to a wafer-level package and a method for forming the wafer-level package.

### BACKGROUND

With the prevalent usage of smartphones, high-performance computing, internet-of-things, and cloud services, there is an explosion in the volume of data generated, transmitted, processed, and stored across the internet. This internet data is typically handled by data centers. A data center interconnects hundreds or thousands of servers. For example, a hyper-scale data center can contain over 5,000 servers. These servers communicate with one another and form the basic building blocks for computing and storage. In order to efficiently handle the large volume of data, these data centers need to meet stringent requirements in relation to power, performance, form-factor, and operating costs. Interconnects play a key role in satisfying these requirements. Due to increasing data rate and propagation length, there is a significant demand to incorporate optical interconnects within and between the data centers.

Effective packaging solutions for integrating optical components to components of other semiconductor technologies are sought. Particularly, effective packaging solutions for co-packaged optics (CPO) to reduce an interconnect distance between optics and other semiconductor components (e.g. silicon photonics, complementary metal-oxide semiconductor (CMOS), silicon-germanium (SiGe), etc.) are wanted. Wafer-level packaging (WLP) has been proposed but this often results in large packages that increase package footprints which are undesirable. There are also challenges in relation to maintaining a mechanical integrity of a wafer-level package during wafer-level package processing which need to be addressed.

It is therefore desirable to provide a wafer-level package and a method for forming the wafer-level package which address the aforementioned problems and/or provides a useful alternative. Further, other desirable features and characteristics will become apparent from the subsequent detailed description and the appended claims, taken in conjunction with the accompanying drawings and this background of the disclosure.

### SUMMARY

Aspects of the present application relate to a wafer-level package and a method for forming the wafer-level package.

In accordance with a first aspect, there is provided a wafer-level package. The wafer-level package comprising: a substrate having electrically conductive interconnects embedded within the substrate, the substrate having a top substrate surface and a bottom substrate surface opposite to the top substrate surface, the bottom substrate surface being adapted to be provided on a printed circuit board (PCB); a first integrated circuit die having an active surface wherein the first integrated circuit die is provided adjacent to an edge portion of a perimeter of the substrate; a mold adapted to hold the first integrated circuit die and the substrate so that the active surface of the first integrated circuit die is in a same plane as the top substrate surface; a first redistribution layer having electrically conductive interconnects embedded within the first redistribution layer, the first redistribution layer being formed on the active surface of the first integrated circuit die and the top substrate surface; and a second integrated circuit die provided on the first redistribution layer, the second integrated circuit die being electrically connected to the first integrated circuit die via the first redistribution layer.

By having a first integrated circuit die provided adjacent to an edge portion of a perimeter of a substrate where an active surface of the first integrated circuit die is being held in the same plane as the top substrate surface and having the second integrated circuit die provided on the first redistribution layer formed on the active surface of the first integrated circuit die and the top substrate surface, interconnects formed for electrically connecting the first integrated circuit die and the second integrated circuit die are shortened. This lowers power consumption by the wafer-level package and the package footprint, as well as reduces parasitic of the interconnects to improve the bandwidth of the interconnects between integrated circuits of the wafer-level package as well as to improve an efficiency for data communication in terms of pJ per bit (pJ/bit). Further, the mold of the wafer-level package is adapted to hold the first integrated circuit and the substrate in place, and this improves the mechanical integrity of the wafer-level package for subsequent wafer-level processing. The substrate comprised in the wafer-level package also provides mechanical strength to the wafer-level package and reduces wafer warpage during wafer-level processing. Further, by having the active surface of the first integrated circuit die being held in the same plane as the top substrate surface by at least the mold, the first redistribution layer can be formed with fine pitch interconnects for providing electrical interconnections to subsequent integrated circuit dice provided, thereby further reducing a distance between these electrical interconnections.

The wafer-level package may comprise a third integrated circuit die provided on the first redistribution layer, the third integrated circuit die may comprise a different type of integrated circuit to that of the first integrated circuit die and the second integrated circuit die.

The third integrated circuit die may be configured to overlap with a portion of the first integrated circuit die and a portion of the substrate.

The third integrated circuit die may be configured to overlap with only a portion of the first integrated circuit die.

The second integrated circuit die provided on the first redistribution layer may be configured to overlap with a portion of the first integrated circuit die.

The wafer-level package may comprise a second redistribution layer having electrically conductive interconnects embedded within the second redistribution layer, the second redistribution layer may be formed on a bottom side of the wafer-level package comprising the bottom substrate surface.

The wafer-level package may comprise primary solder bumps formed on the bottom substrate surface.

The wafer-level package may comprise secondary solder bumps formed on the second redistribution layer or the primary solder bumps. The wafer-level package may comprise an adhesive support or a dummy bump support formed on a bottom side of the wafer-level package devoid of the primary solder bumps.

The first integrated die may be configured to be positioned at less than 250 μm from the edge portion of the perimeter of the substrate.

The wafer-level package may comprise a side-filling layer formed between the first integrated circuit die and the edge portion of the perimeter of the substrate to fill a gap between a side edge of the first integrated circuit die and the edge portion of the perimeter of the substrate. The side-filling layer formed helps to prevent die-shift during formation of the mold of the wafer-level package. This reduces irregular topography formed after molding of the wafer-level package and minimizes die protrusion between integrated circuit dice, thereby improving a plane topography that enables a fine pitch redistribution layer to be formed for connecting the integrated circuit dice of the wafer-level package. This helps to reduce the footprint of the wafer-level package. Moreover, the side-filling layer enhances a mechanical integrity of the wafer-level package to enable dicing of the wafer-level package for subsequent integration with optical couplers with the wafer-level package.

The wafer-level package may comprise: a plurality of integrated circuit dice provided adjacent to other edge portions of the perimeter of the substrate, wherein the mold may be adapted to hold the plurality of integrated circuit dice and the substrate so that an active surface of each of the plurality of integrated circuit dice is in the same plane as the top substrate surface.

The wafer-level package may comprise: a plurality of side-filling layers formed between the first integrated circuit die and the edge portion of the perimeter of the substrate and between side edges of the plurality of integrated circuit dice and the other edge portions of the perimeter of the substrate, wherein the mold may be adapted to hold the first integrated circuit die, the plurality of integrated circuit dice, the plurality of side-filling layers and the substrate so that an active surface of the first integrated circuit die and each of the plurality of integrated circuit dice may be in the same plane as the top substrate surface.

The wafer-level package may comprise perimeter side-filling layers adapted to formed around other side edges of the first integrated circuit die and other side edges of the plurality of integrated circuit dice.

In accordance with a second aspect, there is provided a method for forming a wafer-level package. The method comprising: (i) providing a substrate having electrically conductive interconnects embedded within the substrate, the substrate having a top substrate surface and a bottom substrate surface opposite to the top substrate surface, the bottom substrate surface being adapted to be provided on a printed circuit board (PCB); (ii) providing a first integrated circuit die having an active surface adjacent to an edge portion of a perimeter of the substrate; (iii) forming a mold to hold the first integrated circuit die and the substrate so that the active surface of the first integrated circuit die is in a same plane as the top substrate surface; (iv) forming a first redistribution layer having electrically conductive interconnects embedded within the first redistribution layer, the first redistribution layer being formed on the active surface of the first integrated circuit die and the top substrate surface; and (v) providing a second integrated circuit die on the first redistribution layer, the second integrated circuit die being electrically connected to the first integrated circuit die via the first redistribution layer.

The first integrated circuit die may comprise a photonic integrated circuit (PIC). The second integrated circuit die may comprise an application-specific integrated circuit (ASIC).

The method may comprise: providing a third integrated circuit die on the first redistribution layer, the third integrated circuit die may comprise a different type of integrated circuit to that of the first integrated circuit die and the second integrated circuit die.

The first integrated circuit die may comprise a photonic integrated circuit (PIC) and the third integrated circuit die may comprise an electronic integrated circuit (EIC).

The first integrated circuit die may comprise an electronic integrated circuit (EIC) and the third integrated circuit die may comprise a photonic integrated circuit (PIC).

The first integrated circuit die may comprise a passive chip that provides electrical connections between the second integrated circuit die and the third integrated circuit die and to the bottom substrate surface.

The method may comprise: providing the third integrated circuit die on the first distribution layer to overlap with a portion of the first integrated circuit die and a portion of the substrate.

The method may comprise: providing the third integrated circuit die on the first distribution layer to overlap with only a portion of the first integrated circuit die.

The method may comprise: providing the second integrated circuit die on the first redistribution layer to overlap with a portion of the first integrated circuit die.

The substrate may comprise an organic substrate.

The method may comprise: forming a second redistribution layer having electrically conductive interconnects embedded within the second redistribution layer on a bottom side of the wafer-level package comprising the bottom substrate surface.

The method may comprise: forming primary solder bumps on the bottom substrate surface.

The method may comprise: forming secondary solder bumps on the second redistribution layer or the primary solder bumps.

The method may comprise: forming an adhesive support or a dummy bump support on a bottom side of the wafer-level package devoid of the primary solder bumps.

The method may comprise: providing the first integrated die at less than 250 μm from the edge portion of the perimeter of the substrate.

The method may comprise: forming a side-filling layer between the first integrated circuit die and the edge portion of the perimeter of the substrate to fill a gap between a side edge of the first integrated circuit die and the edge portion of the perimeter of the substrate.

The side-filling layer may comprise an epoxy-based insulating material having filler content with a filler size of not more than 1 μm.

The mold may comprise a liquid epoxy encapsulant having a coefficient of thermal expansion from 5 ppm/° C. to 30 ppm/° C.

The method may comprise: providing a plurality of integrated circuit dice adjacent to other edge portions of the perimeter of the substrate, wherein the step (iii) may comprise forming the mold to hold the plurality of integrated circuit dice and the substrate so that an active surface of each of the plurality of integrated circuit dice is in the same plane as the top substrate surface.

The method may comprise: forming a plurality of side-filling layers between the first integrated circuit die and the edge portion of the perimeter of the substrate and between side edges of the plurality of integrated circuit dice and the other edge portions of the perimeter of the substrate, wherein the step (iii) may comprise forming the mold to hold the first integrated circuit die, the plurality of integrated circuit dice, the plurality of side-filling layers and the substrate so that an active surface of the first integrated circuit die and each of the plurality of integrated circuit dice are in the same plane as the top substrate surface.

The method may comprise forming perimeter side-filling layers around other side edges of the first integrated circuit die and other side edges of the plurality of integrated circuit dice.

At least one of the perimeter side-filling layers may be adapted to fill a gap between adjacent integrated circuit dice.

Each of the first integrated circuit die and the plurality of integrated circuit dice may comprise a photonic circuit having one or more optical couplers formed at an outer edge along a perimeter of the wafer-level package.

Each of the first integrated circuit die and the plurality of integrated circuit dice may comprise a buffer region formed at the outer edge for protecting the one or more optical couplers from damage.

The method may comprise: dicing the outer edge of each of the first integrated circuit die and the plurality of integrated circuit dice to expose the one or more optical couplers.

Wherein the step (iii) may comprise: placing the first integrated circuit die and the substrate on a mold plate, wherein the active surface of the first integrated circuit and the top substrate surface face the mold plate; and forming the mold to hold the first integrated circuit die and the substrate on the mold plate.

The method may comprise: debonding the mold together with the first integrated circuit die and the substrate from the mold plate.

It should be appreciated that features relating to one aspect may be applicable to the other aspects. Embodiments include having the first integrated circuit die provided adjacent to the edge portion of the perimeter of the substrate where the active surface of the first integrated circuit die is being held in the same plane as the top substrate surface, and include having the second integrated circuit die provided on the first redistribution layer formed on the active surface of the first integrated circuit die and the top substrate surface so that interconnects formed for electrically connecting the first integrated circuit die and the second integrated circuit die are shortened. This lowers power consumption by the wafer-level package, lowers the package footprints as well as reduces parasitic of the interconnects to improve the bandwidth of the interconnects between integrated circuits of the wafer-level package as well as to improve an efficiency for data communication in terms of pJ per bit (pJ/bit). Moreover, the mold of the wafer-level package is adapted to hold the first integrated circuit and the substrate in place, and this improves the mechanical integrity of the wafer-level package for subsequent processing. The substrate comprised in the wafer-level package also provides mechanical strength to the wafer-level package and reduces wafer warpage during wafer-level processing. Further, by having the active surface of the first integrated circuit die being held in the same plane as the top substrate surface by at least the mold, the first redistribution layer can be formed with fine pitch interconnects for providing electrical interconnections to subsequent integrated circuit dice provided, thereby further reducing a distance between these electrical interconnections.

In some embodiments, a side-filling layer is formed between the first integrated circuit die and the edge portion of the perimeter of the substrate to fill a gap between a side edge of the first integrated circuit die and the edge portion of the perimeter of the substrate. The side-filling layer formed helps to prevent die-shift during formation of the mold of the wafer-level package. This reduces irregular topography formed after molding of the wafer-level package and minimizes die protrusion between integrated circuit dice, thereby improving a plane topography that enables a fine pitch redistribution layer to be formed for connecting the integrated circuit dice of the wafer-level package. This further reduces the footprint of the wafer-level package. Moreover, the side-filling layer enhances a mechanical integrity of the wafer-level package to enable dicing of the wafer-level package for subsequent integration of optical couplers of the wafer-level package with external optical components.

### BRIEF DESCRIPTION OF THE DRAWINGS

Embodiments will now be described, by way of example only, with reference to the following drawings, in which:

FIGS. 1A and 1B show schematics of a cross-section of wafer-level packages in accordance with embodiments, where FIG. 1A shows a schematic of a cross-section of a wafer level package having a redistribution layer formed at a back surface of the substrate without bumps and FIG. 1B shows a schematic of a cross-section of a wafer-level package having bumps formed on a back surface of the substrate;

FIG. 2 is a flowchart showing steps of a method for forming a wafer-level package in accordance with an embodiment;

FIG. 3 is a flowchart showing steps of a method for forming a mold to hold an integrated circuit die to a substrate in accordance with an embodiment;

FIGS. 4A, 4B, 4C, 4D, 4E, 4F, 4G, 4H and 4I show a series of schematics to illustrate a process flow for forming the wafer-level package of FIG. 1A in accordance with an embodiment, where FIG. 4A shows a schematic of integrated circuit dice and a substrate for wafer-level packaging, FIG. 4B shows a schematic to illustrate placement of the integrated circuit dice and the substrate on a mold plate, FIG. 4C shows a schematic to illustrate formation of side-filling layers at edge portions of the integrated circuit dice, FIG. 4D shows a schematic to illustrate wafer-level molding to encapsulate the integrated circuit dice, the substrate and the side-filling layers, FIG. 4E shows a schematic to illustrate a debonded reconstituted wafer comprising the molded integrated circuit dice, substrate and side-filling layers, FIG. 4F shows a schematic to illustrate formation of a first redistribution layer (RDL) on active surfaces of the integrated circuit dice and the top substrate surface, FIG. 4G shows a schematic to illustrate formation of a second redistribution layer (RDL) on a bottom surface of the integrated circuit dice and the substrate after a back-grinding process, FIG. 4H shows a schematic to illustrate dicing of the integrated circuit dice to expose edge couplers and FIG. 4I shows a schematic to illustrate an assembly of the wafer-level package to include solder balls and other integrated circuit dice in the wafer-level package;

FIGS. 5A, 5B, 5C, 5D, 5E, 5F, 5G, 5H and 5I show a series of schematics to illustrate a process flow for forming the wafer-level package of FIG. 1B in accordance with an embodiment, where FIG. 5A shows a schematic of integrated circuit dice and a substrate having solder bumps for wafer-level packaging, FIG. 5B shows a schematic to illustrate placement of the integrated circuit dice and the substrate on a mold plate, FIG. 5C shows a schematic to illustrate formation of side-filling layers at edge portions of the integrated circuit dice, FIG. 5D shows a schematic to illustrate wafer-level molding to encapsulate the integrated circuit dice, the substrate and the side-filling layers, FIG. 5E shows a schematic to illustrate a debonded reconstituted wafer comprising the molded integrated circuit dice, substrate and side-filling layers, FIG. 5F shows a schematic to illustrate formation of a first redistribution layer (RDL) on active surfaces of the integrated circuit dice and the top substrate surface, FIG. 5G shows a schematic to illustrate back-grinding of a bottom side of the reconstituted wafer to expose the solder bumps of the substrate, FIG. 5H shows a schematic to illustrate dicing of the integrated circuit dice to expose edge couplers and FIG. 5I shows a schematic to illustrate an assembly of the wafer-level package to include other integrated circuit dice in the wafer-level package;

FIG. 6 shows a schematic of a cross-section of a wafer-level package having dummy bumps formed on a bottom side of the wafer-level package to provide support for the wafer-level package during a subsequent assembly process in accordance with an embodiment;

FIG. 7 shows a schematic of a cross-section of a wafer-level package comprising a high bandwidth memory (HBM), a graphics processing unit (GPU) and a driver unit formed on a RDL on a top substrate side in accordance with an embodiment;

FIG. 8 shows a schematic of a cross-section of a wafer-level package comprising a switch component (e.g. ASIC) formed on a RDL on a top substrate side in accordance with an embodiment;

FIG. 9 shows a schematic of a cross-section of the wafer-level package of FIG. 1A to illustrate a short signal path between a switch component (e.g. ASIC) and other integrated circuit dice formed on a redistribution layer on a top surface side of the wafer-level package in accordance with an embodiment;

FIGS. 10A, 10B, 10C and 10D show schematics of a cross-section of a portion of a wafer-level package to illustrate various arrangements of a switch component and integrated circuit dice formed on a redistribution layer on a top surface side of the wafer-level package in accordance with embodiments, where FIG. 10A shows a schematic of a cross-section of a portion of a wafer-level package having an electronic integrated circuit (EIC) overlapping an embedded photonic integrated circuit (PIC) and a substrate, FIG. 10B shows a schematic of a cross-section of a portion of a wafer-level package having an EIC placed entirely above an embedded PIC, FIG. 10C shows a schematic of a cross-section of a portion of a wafer-level package having an EIC overlapping an embedded photonic integrated circuit (PIC) and a substrate and another EIC place entirely above the substrate and FIG. 10D shows a cross-section of a portion of a wafer-level package having a PIC placed entirely above an embedded EIC;

FIGS. 11A and 11B show schematics illustrating process flows in relation to formation of side-filling layers and subsequent molding of a wafer-level package in accordance with two embodiments, where FIG. 11A shows schematics illustrating a process flow for forming side-fill layers at two or more sides of embedded integrated circuit die and FIG. 11B shows schematics illustrating a process flow for forming side-fill layers only in gaps between a substrate and a corresponding embedded integrated circuit die;

FIG. 12 shows a schematic of a top view of the wafer-level package of FIG. 1A in accordance with an embodiment;

FIGS. 13A and 13B show schematics of a wafer-level package having side-filling layers in accordance with an embodiment, where FIG. 13A shows a schematic of a top view of the wafer-level package with respect to a wafer and FIG. 13B shows a schematic of a cross-section of the wafer-level package;

FIGS. 14A, 14B, 14C show schematics of top views of portions of wafer-level packages having different configurations of side-filling layers in accordance with embodiments, where FIG. 14A shows a schematic of a top view of a portion of a wafer-level package having side-filling layers applied only at a gap between a substrate and an embedded integrated circuit die, FIG. 14B shows a schematic of a top view of a portion of a wafer-level package having side-filling layers applied around all sides of an embedded integrated circuit die inclusive of a gap between a substrate and the embedded integrated circuit die and FIG. 14C shows a schematic of a top view of a portion of a wafer-level package having side-filling layers applied around all sides of embedded integrated circuit dice inclusive of gaps between a substrate and the embedded integrated circuit dice and a gap between adjacent embedded integrated circuit dice;

FIG. 15 shows a schematic of a top view and a cross-sectional view of a wafer-level package with outer edges of embedded integrated circuit dice being diced to expose one or more optical couplers in accordance with an embodiment;

FIGS. 16A and 16B show schematics of cross-sections of a wafer-level package that underwent dicing of the outer edges of embedded integrated circuit dice in accordance with an embodiment, where FIG. 16A shows a schematic of a cross-section of the wafer-level package being diced to expose one or more optical couplers of the embedded integrated circuit dice and FIG. 16B shows a schematic of a cross-section of the wafer-level package where external optical fibers are aligned to the exposed one or more optical couplers;

FIG. 17 shows a symmetric quarter model for use in evaluating warpage of a wafer with embedded substrates and a wafer without embedded substrates in accordance with an embodiment;

FIGS. 18A and 18B show simulation results in relation to warpage of a wafer with embedded substrates and warpage of a wafer without embedded substrates using the symmetric quarter model of FIG. 17 in accordance with an embodiment, where FIG. 18A shows simulation results in relation to the warpage of the wafer with embedded substrates and FIG. 18B shows simulation results in relation to the warpage of the wafer without embedded substrates;

FIGS. 19A and 19B show an example of schematics of wafer-level packages provided on a wafer for a feasibility experiment in accordance with an embodiment, where FIG. 19A shows schematics of a top view of the wafer-level packages placement on the wafer and a top view of one of the wafer-level package and FIG. 19B shows a schematic of a cross-section of the wafer-level package of FIG. 19A; and

FIGS. 20A and 20B show photographs of the wafer-level packages provided on a wafer for the feasibility experiment of FIGS. 19A and 19B, where FIG. 20A shows a photograph of the wafer-level packages placement on the wafer and FIG. 20B shows a photograph of a top view of one of the wafer-level packages used in FIG. 20A after molding.

### DETAILED DESCRIPTION

Exemplary embodiments relate to a wafer-level package and a method for forming the wafer-level package.

It is appreciated that in the present disclosure, the use of the singular includes the plural unless specifically stated otherwise. It should be noted that, as used in the specification and the appended claims, the singular forms “a”, “an” and “the” include plural referents unless the context clearly dictates otherwise. Further, the use of the term “including”, “comprising”, and “having” as well as other forms, such as “include”, “comprise”, “have” are not considered limiting.

As used herein, the term “and/or” includes any and all combinations of one or more of the associated listed items.

The present embodiments involve a wafer-level package and forming of the wafer-level package, particularly in relation to forming of a heterogeneous wafer-level package to integrate photonic integrated circuits (PICs), application-specific integrated circuit (ASIC), and/or electronic integrated circuit (EICs) using an embedded substrate. Embodiments are associated with integration of separately manufactured components into a higher-level assembly System-in-Package (SiP) using fan-out wafer-level packaging (FOWLP) which facilitates integration of integrated circuits (ICs) from different technologies.

The present embodiments aim to: (i) address or improve a mechanical integrity of large wafer-level-package (e.g. >40 mm×40 mm) processing, (ii) provide a fine-pitch on-package high-bandwidth interconnects, and (iii) provide short package interconnects (the length of the package interconnects can vary from centimeter and millimeter ranges to micrometer ranges) between integrated circuit dice comprising application-specific integrated circuit (ASIC), high-bandwidth memory (HBM), electronic integrated circuit (EIC) and photonic integrated circuit (PIC) for high-speed performance. Exemplary package architectures are also discussed in relation to a three-dimensional (3D) co-packaged optics platform capable of interfacing directly with an ASIC.

The industry is looking for effective packaging solutions for integrating optical components with electronic components. In conventional platforms, discrete components are manually assembled and packaged, resulting in low device densities with physically large solutions which cannot be used as wafer-level packaging. In such cases, the switch or ASIC and transceivers (pluggable modules) are separated by longer interconnects due to their architecture and cannot achieve high-speed interconnects. Examples of such platforms include connection of an optical component to an electronic component (e.g. a switch or ASIC) using pluggable optics and connection of an optical component to an electronic component (e.g. a switch or ASIC) using on-board optics with a shortened interconnection.

Technology progresses and co-packaged optics (CPO) were introduced to shorten the interconnection between optical components and electronic components. Examples of these include connection of an optical component to an electronic component (e.g. a switch or ASIC) using co-packaged optics (CPO) where an interconnect is used between the optical component and the electronic component which can be shortened, and a package where an optical component can be integrated with an electronic component using an interposer in a 3D CPO.

Examples of CPO structures may include (i) a CPO structure comprising a switch component provided between two photonic integrated circuits (PICs) on a substrate where electronic components are formed over a redistribution layer above the PICs and are connected to the switch component via a through-silicon vias (TSV) in the PICs to achieve a 2.5D CPO structure; (ii) a CPO structure comprising a switch component provided on a low loss substrate at one end portion of a low loss interposer, and an electronic integrated circuit and a photonic integrated circuit provided on a low loss substrate and a high-speed socket at the other end portion of the low loss interposer where a signal path between the switch component and the electronic integrated circuit is via the low loss substrate at one end of the low loss interposer, the low loss interposer, and the high speed socket and the low loss interposer at the other end of the low loss interposer; and (iii) a CPO structure comprising a graphic processing unit (GPU) with a high bandwidth memory (HBM) provided over a through-silicon interposer (TSI) on a portion of a substrate and an electronic integrated circuit (EIC) provided over a redistribution layer formed on a PIC provided at another portion of the substrate.

However, these examples each have their issues. For example, the example (i) includes a substantial interconnect length and the presence of the TSV increases processing cost and poses a limit on the scalability of such a structure; the example (ii) includes a long electrical signal path between the photonic integrated circuit and the switch component (e.g. an ASIC) which increases the power consumption of such a CPO structure; and the example (iii) includes a signal path which requires through-silicon vias and a through-silicon interposer (TSI) and these increase processing difficulties and costs. The long interconnects in these examples also cause high-speed signal loss which is not desirable. Further, the aforementioned CPO structures are based on components being assembled on a substrate and interconnected using long vertical and horizontal interconnects which cause high speed signal loss.

To improve and/or alleviate the aforementioned issues associated with the conventional CPO platforms as discussed, embodiments of the present disclosure includes a wafer-level package comprising a first integrated circuit die provided adjacent to an edge portion of a perimeter of a substrate where an active surface of the first integrated circuit die is being held in a same plane as a top substrate surface and a second integrated circuit die provided on a first redistribution layer formed on the active surface of the first integrated circuit die and the top substrate surface. In this way, interconnects formed for electrically connecting the first integrated circuit die and the second integrated circuit die can be shortened.

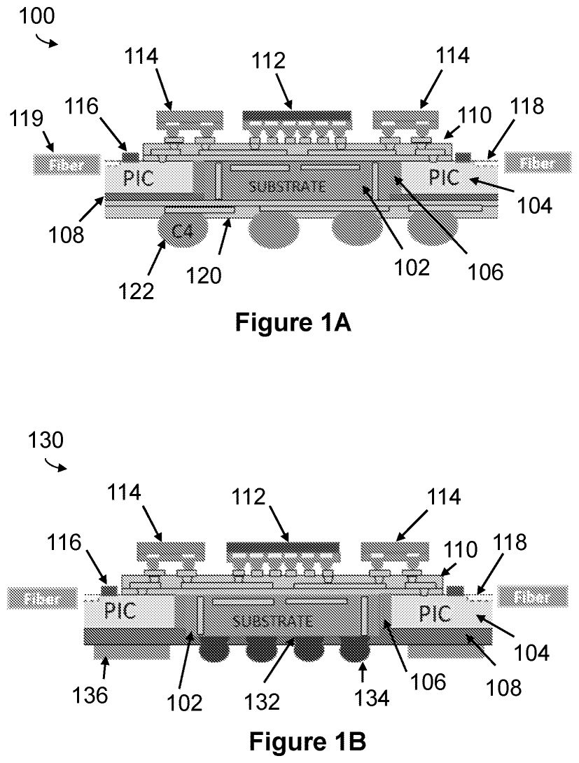

FIGS. 1A and 1B show schematics of cross-sections of wafer-level packages in accordance with embodiments. The wafer-level packages as shown in relation to FIGS. 1A and 1B can be used in data-center applications.

FIG. 1A shows a schematic of a cross-sectional view of a wafer-level package 100 in accordance with a first embodiment. The wafer-level package 100 comprises a substrate 102 having electrically conductive interconnects embedded within the substrate 102. The substrate 102 has a top substrate surface and a bottom substrate surface opposite to the top substrate surface where the bottom substrate surface is adapted to be provided on a printed circuit board (PCB) (see e.g. in relation to FIG. 9 below).

Integrated circuit dice 104 (e.g. photonic integrated circuits (PICs) as shown in FIG. 1A) are provided adjacent to edge portions of a perimeter of the substrate 102. In the present embodiment, side-filling layers 106 are provided between the integrated circuit dice 104 and the edge portions of the perimeter of the substrate 102 to fill gaps between side edges of the integrated circuit dice 104 and the edge portions of the perimeter of the substrate 102. The side-filling layers 106 comprise an epoxy-based insulating material having filler content with a filler size of not more than 1 μm in the present embodiment, but other suitable insulating material may be used. The wafer-level package 100 includes a mold 108 adapted to hold the integrated circuit dice 104 and the substrate 102 so that an active surface of the integrated circuit dice 104 is in substantially the same plane as the top substrate surface. A first redistribution layer (RDL) 110 having electrically conductive interconnects embedded within the first redistribution layer 110 is formed on the active surface of the integrated circuit dice 104 and the top substrate surface. One or more integrated circuit dice 112, 114 are then provided on the first redistribution layer 110. In the present embodiment, the integrated circuit die 112 includes an application-specific integrated circuit (ASIC) and the integrated circuit dice 114 include electronic integrated circuits (EICs). As shown in FIG. 1A, the ASIC 112 and the EICs 114 are electrically connected to the PICs 104 via the first redistribution layer 110. A laser diode 116 and an optical coupler 118 can be formed on the PICs 104 for optically connecting to other external electrical components (e.g. via optical fibers 119). In the present embodiment, a second redistribution layer (RDL) 120 is formed on the bottom substrate surface of the wafer-level package 100. Solder bumps 122 are then formed on the second redistribution layer 120 for electrically connecting to a PCB. Both the first and second RDLs 110, 120 include lateral and/or vertical interconnections for connecting to surrounding integrated circuits or components.

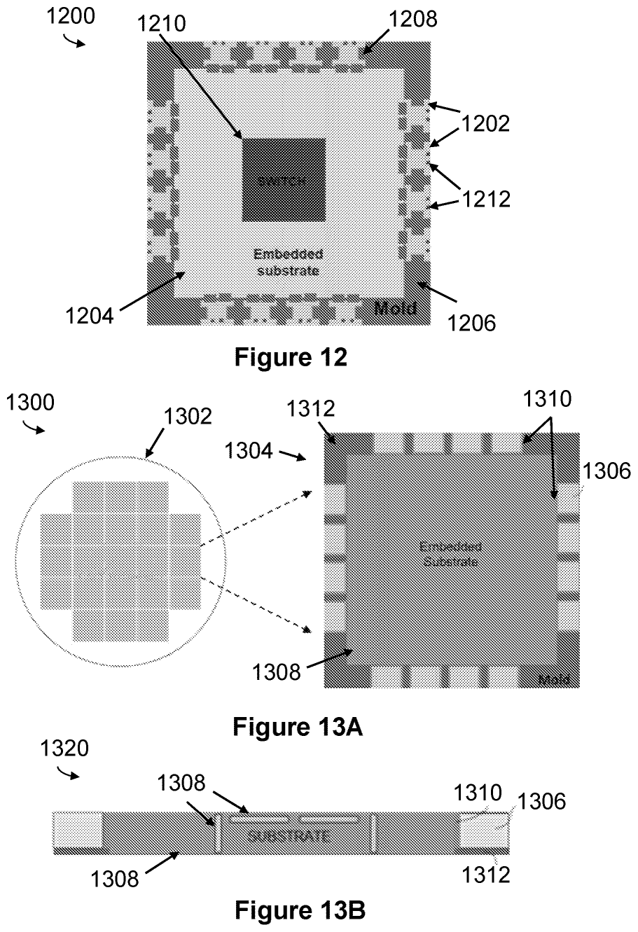

The substrate 102 having embedded electrically conductive interconnects provide lateral and vertical interconnections to facilitate die to die interconnections as well as electrical connections to external electrical components (e.g. other dice or packages). The embedded substrate 102 also provides mechanical strength to the wafer-level package for minimizing stress or warpage. By having the active surface of the PICs 104 being substantially in plane to the top substrate surface, at least the first redistribution layer 110 can be formed with fine pitch interconnect lines (having <2 μm line and/or spacing). This improves an interconnect density for the RDL 110, thereby allowing a higher density of the integrated circuits to be formed for connecting with the RDL 110 and reducing a footprint or size of the wafer-level package. As would be made clearer by a top planar view of the wafer-level package illustrated in relation to FIG. 12 below, the present wafer-level package 100 enables multiple integrated circuits (ICs) to be formed or provided adjacent/around the substrate, further improving a density of the ICs for wafer-level package integration.

Further, in the present embodiment, side-filling layers 106 are formed between the PICS 104 and the edge portions of the perimeter of the substrate 102. For typical Fan-Out Wafer-Level Packaging (FOWLP) integration, the hindrance to creating fine pitch top side RDL is due to irregular topography formed due to die protrusion effect after molding. Embedded die whose surface extends above or below a mold surface or a substrate surface limits multichip integration and RDL scaling. The side-filling layers 106 formed help to prevent die-shift during formation of the mold 108 of the wafer-level package 100. This reduces irregular topography formed after molding of the wafer-level package 100 and minimizes die protrusion between integrated circuit dice 104, thereby improving a plane topography that enables a fine pitch redistribution layer 110 to be formed for connecting the integrated circuit dice of the wafer-level package 100. This further reduces the footprint of the wafer-level package 100. Moreover, the side-filling layer 106 enhances a mechanical integrity of the wafer-level package 100 to enable dicing of the wafer-level package 100 for subsequent integration with optical couplers with the wafer-level package 100.

Further, in the present embodiments, integrated circuit die-to-integrated circuit die spacing and/or integrated circuit die-to-substrate spacing are reduced to less than 50 μm. This also helps to reduce die protrusion effect for improving plane topography for formation of the fine pitch first RDL 110. For formation of the second RDL 120, any planarity issue in relation to the bottom substrate surface can be resolved by a back-grinding process to ensure a flat surface for forming of the second RDL 120. This also enables the second RDL 120 to have a fine pitch with a pitch density/resolution of less than 2 μm per line or spacing.

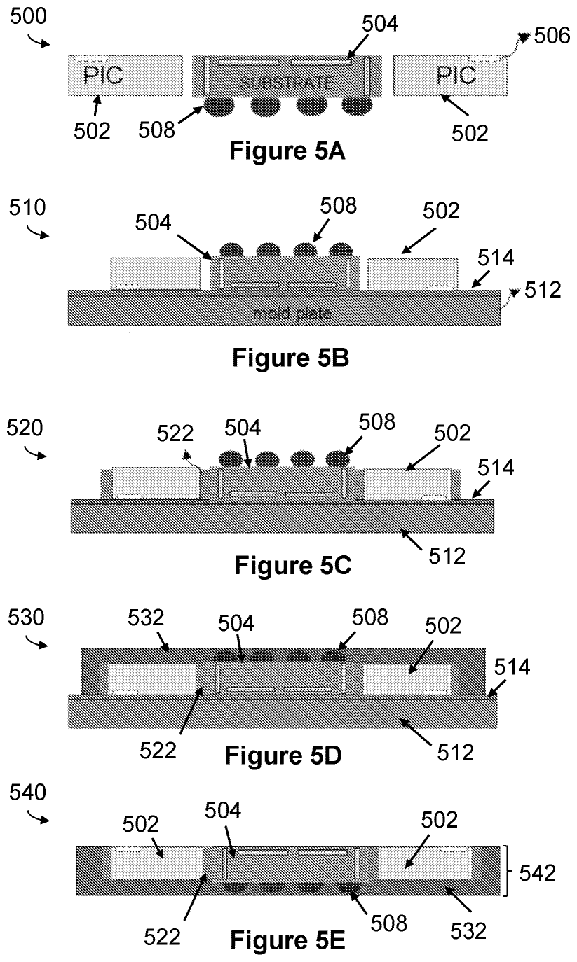

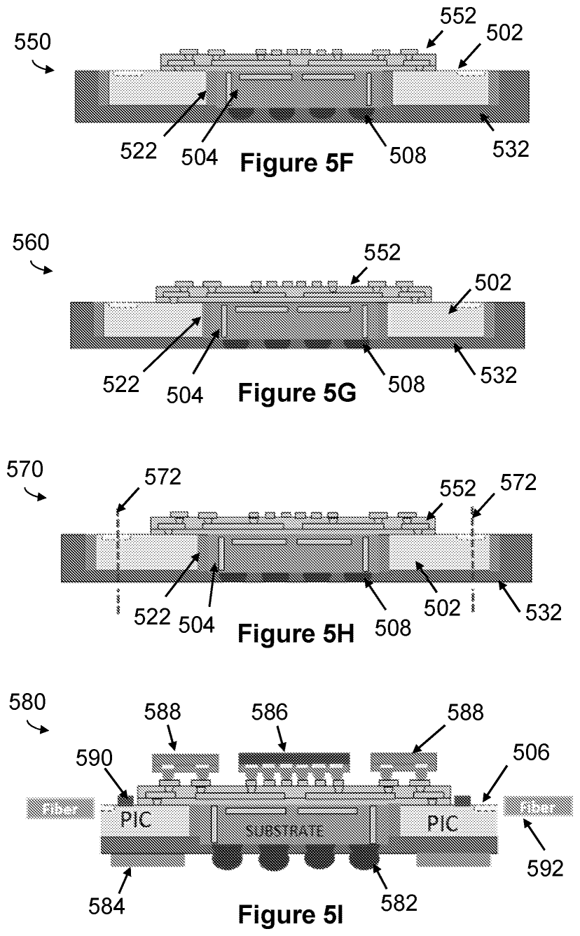

FIG. 1B shows a schematic of a cross-sectional view of a wafer-level package 130 according to a second embodiment. Similar features as discussed in relation to the wafer-level package 100 of FIG. 1A are labelled with the same reference signs and their descriptions are not repeated here for succinctness. The difference between the first embodiment as shown in relation to FIG. 1A and the present embodiment as shown in relation to FIG. 1B relates to solder bumps 132, 134 formed at the bottom substrate surface of the wafer-level package 130. As would be made clear in relation to FIGS. 5A to 5I, primary solder bumps 132 were first formed on the bottom substrate surface (in direct contact with the bottom substrate surface) prior to molding. Subsequently during an assembly stage of the wafer-package formation process, the mold at the bottom substrate side was back-grinded to expose portions of these primary solder bumps 132. Secondary solder bumps 134 are subsequently formed in electrical contact with the primary solder bumps 132 as shown in FIG. 1B. In the present embodiment, adhesive supports 136 are formed on a bottom side of the wafer-level package devoid of the primary and secondary solder bumps to provide support for the wafer-level package for integrating with the PCB.

The wafer-level package architectures as described in relation to FIGS. 1A and 1B above reduce interconnect lengths between the ASIC 112, PICs 104 and EICs 114 substantially. This allows high-speed and broad bandwidth signals, thereby providing a solution to future needs in applications associated with hyperscale datacenter (HDC) and/or high performance computing (HPC). The fine pitch redistribution layers (RDLs) 110, 120 provide high-density high bandwidth interconnection between different components of the wafer-level packages 100, 130. Further, the afore-described wafer-level package architectures can be coupled with cost-effective wafer-level processes for integrating components from different technologies, where the embedded PICs connecting with flip-chip EICs via the top RDL 110 avoids expensive and area-consuming through-silicon vias (TSVs). The present wafer-level packages 100, 130 are manufactured on a wafer-level, thereby allowing wafer-level processing, packaging, and testing, and reduces manufacturing costs.

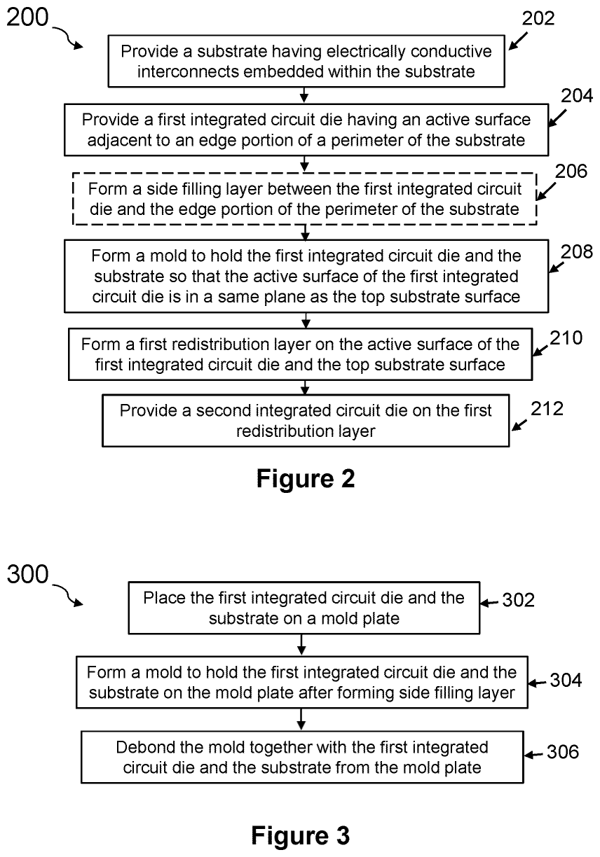

FIG. 2 is a flowchart showing steps of a method 200 for forming a wafer-level package in accordance with an embodiment.

In step 202, a substrate having electrically conductive interconnects embedded within the substrate is provided. The substrate includes a top substrate surface and a bottom substrate surface opposite to the top substrate surface, where the bottom substrate surface is adapted to be subsequently provided on a printed circuit board (PCB).

In step 204, a first integrated circuit die (e.g. a PIC die) having an active surface is provided adjacent to an edge portion of a perimeter of the substrate. It is not necessary that a side edge of the first integrated circuit die is in direct contact with the edge portion of the perimeter of the substrate as any gap between the side edge of the first integrated circuit die and the substrate can be filled (see below). In an embodiment, the first integrated die is configured to be positioned at less than 250 μm from the edge portion of the perimeter of the substrate. As will be made clear in relation to FIG. 12, in an embodiment, a plurality of integrated circuit dice can be provided adjacent to edge portions of the perimeter of the substrate.

In an optional step 206 (shown in dotted lines), a side-filling layer is formed between the first integrated circuit die and the edge portion of the perimeter of the substrate to fill a gap between the side edge of the first integrated circuit die and the edge portion of the perimeter of the substrate. The side-filling layer may comprise an epoxy-based insulating material having filler content with a filler size of not more than 1 μm.

The optional step 206 can also be applied to an embodiment where a plurality of integrated circuit dice are provided adjacent to edge portions of the perimeter of the substrate. In this case, a plurality of side-filling layers are formed between side edges of the plurality of integrated circuit dice and the edge portions of the perimeter of the substrate. The side-filling layers can be formed around all or some of the side edges of the first integrated circuit die or the plurality of integrated circuit dice. Where a plurality of integrated circuit dice are provided, in an embodiment, at least one of the perimeter side-filling layers is adapted to fill a gap between adjacent integrated circuit dice.

In step 208, a mold is formed to hold the first integrated circuit die and the substrate so that the active surface of the first integrated circuit die is in a same plane or substantially the same plane as the top substrate surface. In an embodiment where a side-filling layer is formed between the first integrated circuit die and the edge portion of the perimeter of the substrate in the step 206, the mold is adapted to hold the first integrated circuit die, the side-filling layer and the substrate so that the active surface of the first integrated circuit die is in a same plane or substantially the same plane as the top substrate surface. The mold may comprise a liquid epoxy encapsulant having a coefficient of thermal expansion from 5 ppm/° C. to 30 ppm/° C. In an embodiment where a plurality of integrated circuit dice are provided adjacent to edge portions of the perimeter of the substrate, the mold is formed to hold the plurality of integrated circuit dice, the plurality of side-filling layers and the substrate so that active surfaces of the plurality of integrated circuit dice are in the same plane or in substantially the same plane as the top substrate surface.

In step 210, a first redistribution layer having electrically conductive interconnects embedded within the first redistribution layer is formed on the active surface of the first integrated circuit die and the top substrate surface. The first distribution layer has electrically conductive interconnects for providing interconnection between different integrated circuit dice of the wafer-level package. In an embodiment where a plurality of integrated circuit dice are provided adjacent to edge portions of the perimeter of the substrate, the first redistribution layer is formed on the active surfaces of the plurality of integrated circuit dice and the top substrate surface.

In step 212, a second integrated circuit die is formed on the first redistribution layer. The second integrated circuit die comprises an application-specific integrated circuit (ASIC) in the present embodiment and is electrically connected to the first integrated circuit die via the first redistribution layer. The ASIC includes a switch or a graphic processing unit or the like. It should be appreciated that other integrated circuit die or dice, or further integrated circuit die or dice can be formed on the first redistribution layer according to a requirement or application of the wafer-level package.

FIG. 3 is a flowchart showing steps of a method 300 for forming a mold to hold an integrated circuit die to a substrate in accordance with an embodiment.

In step 302, the first integrated circuit die and the substrate are placed on a mold plate, where the active surface of the first integrated circuit and the top substrate surface face the mold plate. In an embodiment where a plurality of integrated circuit dice are provided adjacent to edge portions of the perimeter of the substrate, the plurality of integrated circuit dice and the substrate are placed on the mold plate so that the active surfaces of the plurality of integrated circuit dice and the top substrate surface face the mold plate.

In step 304, the mold is formed to hold the first integrated circuit die and the substrate on the mold plate. In an embodiment where a plurality of integrated circuit dice are provided adjacent to edge portions of the perimeter of the substrate, the mold is formed to hold the plurality of integrated circuit dice and the substrate so that an active surface of each of the plurality of integrated circuit dice is in the same plane or in substantially the same plane as the top substrate surface.

In step 306, the mold together with the first integrated circuit die and the substrate are debonded from the mold plate. In an embodiment where a plurality of integrated circuit dice are provided adjacent to edge portions of the perimeter of the substrate, the plurality of the integrated circuit dice and the substrate are debonded from the mold plate. The molded integrated circuit die/dice and the substrate can then be used in subsequent processing steps (e.g. the steps 210, 212 as afore-described).

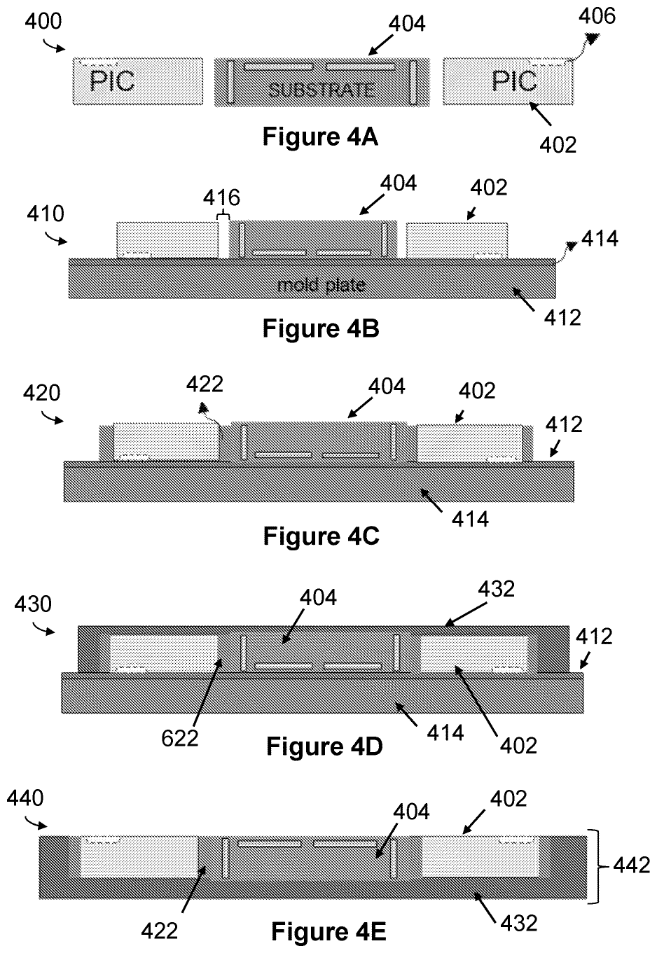

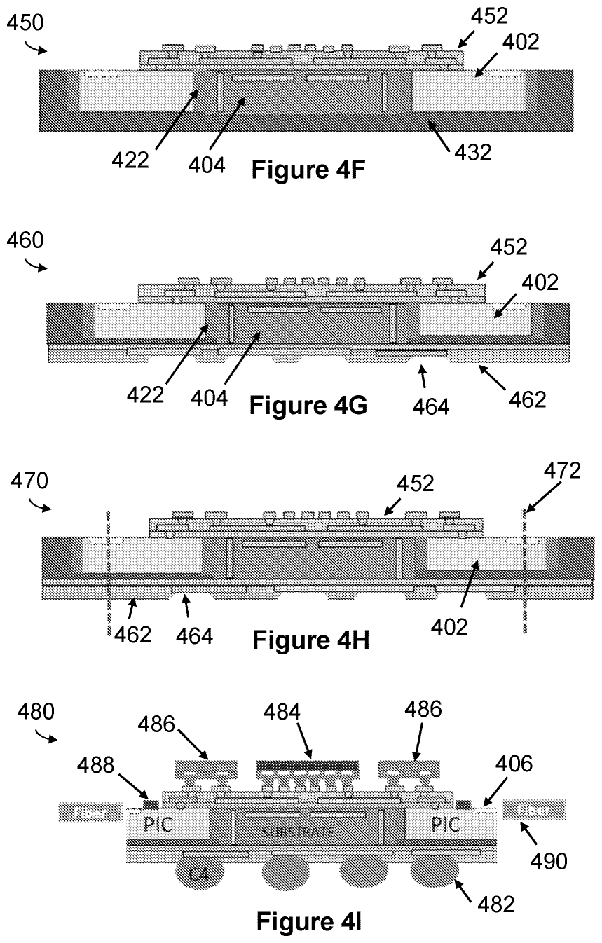

FIGS. 4A to 4I and 5A to 5I show two series of schematics for forming the wafer-level packages of the first and second embodiments as shown in relation to FIGS. 1A and 1B, respectively. A Fan-Out wafer-level package (FOWLP) processing for integrating components of different semiconductor technologies is employed.

FIGS. 4A to 4I show a series of schematics to illustrate a process flow for forming the wafer-level package 100 of FIG. 1A where a mold first FOWLP process flow is employed.

FIG. 4A shows a schematic 400 of two integrated circuit dice 402 and a substrate 404 for wafer-level packaging. The integrated circuit dice 402 include photonic integrated circuit (PIC) dice as shown in the wafer-level package 100 of FIG. 1A. The substrate 404 includes electrically conductive interconnects embedded within the substrate 404. The embedded interconnects of the substrate 404 provide electrical connections between two or more integrated circuit dice within the wafer-level package. The substrate 404 also reinforces and provides mechanical integrity for large wafer-level packages (e.g. >40 mm×40 mm), and facilitates subsequent wafer-level package processing, such as RDL processing, by maintaining wafer warpage within predetermined processing limits, for example by having wafer warpage less than 2 mm. In the present embodiment, a stopper 406 (e.g. comprising silicon) is used to prevent mold seeping in a subsequent step.

FIG. 4B shows a schematic 410 illustrating placement of the integrated circuit dice 402 and the substrate 404 on a mold plate 412 for forming a reconstituted molded wafer for subsequent processes. The integrated circuit dice 402 and the substrate 404 are picked and placed face down on an adhesive layer 414 attached to the mold plate 412. As shown in FIG. 4B, the top substrate surface and the active surfaces of the integrated circuit dice 402 are therefore facing and attached to the mold plate via the adhesive layer 414. In the present embodiment, the integrated circuit dice 402 are placed at less than 250 μm from the edge portions of the perimeter of the substrate 404. A gap 416 (of less than 250 μm) between the integrated circuit dice 402 and the edge portions of the perimeter of the substrate 404 is shown in the schematic 410.

FIG. 4C shows a schematic 420 illustrating formation of side-filling layers 422 at edge portions of the integrated circuit dice 402. Once the integrated circuit dice 402 and the substrate 404 are in place and attached to the mold plate 412, side-filling material is applied in liquid form in gaps between the integrated circuit dice 402 and the edge portions of the perimeter of the substrate 404. In the present embodiment as shown in relation to FIG. 4C, the side-filling material is also applied to other side edges (e.g. outer side edges) of the integrated circuit dice 402. The side-filling material is then cured to form the solid side-filling layers 422. In the present embodiment, the side-filling material includes an epoxy based insulating material having filler content with a filler size of not more than 1 μm. The side-filling material of the present embodiment possesses excellent flow ability which allows narrow gap penetration between the substrate and integrated circuit dice, thereby providing good reliability during thermal cycles. The side-fill material in liquid form can be dispensed by employing an automated tool or manually through a syringe needle size of 22 gauge to 25 gauge. The side-filling material is applied in the liquid form and is cured at 150° C. for 30 min to 1 hour to form the side-filling layers 422.

FIG. 4D shows a schematic 430 illustrating wafer-level molding to encapsulate the integrated circuit dice 402, the substrate 404 and the side-filling layers 422. The mold 432 in the present embodiment includes a liquid epoxy encapsulant having a low coefficient of thermal expansion from 5 ppm/° C. to 30 ppm/° C. This allows low warpage for large-size wafer-level package applications employing this liquid molding process.

FIG. 4E shows a schematic 440 illustrating a reconstituted wafer 442 debonded from the mold plate 412. The reconstituted wafer 442 comprises the molded integrated circuit dice 402, the substrate 404 and the side-filling layers 422 formed in the mold 432. The schematic 440 shows a flipped reconstituted wafer 442 so that the top substrate surface and the active surfaces of the integrated circuit dice 402 are facing up and are left exposed (i.e. free from the mold 432).

FIG. 4F shows a schematic 450 illustrating a first redistribution layer (RDL) 452 formed on active surfaces of the integrated circuit dice 402 and the top substrate surface of the substrate 404. As shown in the schematic 450, the first RDL 452 is formed on portions (i.e. not in entirety) of the active surfaces of the integrated circuit dice 402 and is formed on the entire top substrate surface. With the aforementioned molding process and side-filling process, an even surface topology can be obtained after molding of the wafer-level package with minimized die protrusion between the integrated circuit dice 402. This enables a fine pitch first RDL 452 to be formed. In the present embodiment, the first RDL 452 includes a pitch density/resolution of less than 2 μm per line or spacing.

FIG. 4G shows a schematic 460 illustrating formation of a second redistribution layer (RDL) 462 on a bottom surface of the integrated circuit dice 402 and the substrate 404 after a back-grinding process. In the present embodiment, the reconstituted wafer 442 is temporarily bonded to a transfer wafer for performing the back-grind process. The back-grinding process exposes at least a bottom substrate surface of the substrate 404 so that interconnects of the second RDL 462 can be electrically connected to the embedded interconnects in the substrate 404. Further, there are openings 464 formed by e.g. photolithography processes in the second RDL 462 where dielectric material of the second RDL 462 is selectively removed to expose the interconnects of the second RDL for forming subsequent electrical connection with solder balls (see e.g. FIG. 4I below).

FIG. 4H shows a schematic 470 illustrating lines 472 for dicing of the integrated circuit dice 402 to expose edge couplers. As shown in the schematic 470, the dicing is at the deep trenches formed in the integrated circuit dice 402. The exposed edge couplers can then be used to couple with external optical components optically.

FIG. 4I shows a schematic 480 illustrating an assembly of the wafer-level package to include solder balls 482 and other integrated circuit dice in the wafer-level package. The solder balls 482 are used for electrically connecting the wafer-level package to a printed circuit board (PCB) in subsequent processes. In the present embodiment, the other integrated circuit dice includes an ASIC 484 and two electronic integrated circuit dice 486 (e.g. drivers or optical transimpedance amplifiers (TIA)). Laser diodes 488 are also provided and connected to the integrated circuit dice 402 (being PICs) and these can be coupled externally via the exposed edge couplers and optical fibers 490.

FIGS. 5A, 5B, 5C, 5D, 5E, 5F, 5G, 5H and 5I show a series of schematics to illustrate a process flow for forming the wafer-level package 130 of FIG. 1B.

FIG. 5A shows a schematic 500 of integrated circuit dice 502 and a substrate 504 having solder bumps 508 for wafer-level packaging. The integrated circuit dice 502 include photonic integrated circuit dice as shown in the wafer-level package 130 of FIG. 1B. Similar to the first embodiment, the substrate 504 includes electrically conductive interconnects embedded within the substrate 504. A stopper 506 (e.g. comprising silicon) is similarly used in the present embodiment to prevent mold seeping in a subsequent process step. In addition, in the present embodiment, solder bumps 508 are formed at a bottom substrate surface of the substrate 504.

FIG. 5B shows a schematic 510 illustrating placement of the integrated circuit dice 502 and the substrate 504 on a mold plate 512 for forming a reconstituted molded wafer for subsequent processes. Similar to the earlier embodiment, the integrated circuit dice 502 and the substrate 504 having the solder bumps 508 are placed face down on an adhesive layer 514 attached to the mold plate 512. As shown in FIG. 5B, the top substrate surface and the active surfaces of the integrated circuit dice 502 are therefore facing the mold plate, while the solder bumps 508 at the bottom substrate surface are now faced up. Similar to the earlier embodiment, the integrated circuit dice 502 in the present embodiment are placed at less than 250 μm from the edge portions of the perimeter of the substrate 504.

FIG. 5C shows a schematic 520 illustrating formation of side-filling layers 522 at edge portions of the integrated circuit dice 502. Once the integrated circuit dice 502 and the substrate 504 with the solder bumps 508 are in place and attached to the mold plate 512, side-filling material is applied in liquid form in gaps between the integrated circuit dice 502 and the edge portions of the perimeter of the substrate 504. In the present embodiment, similar to the earlier embodiment, the side-filling material is also applied to other side edges (e.g. outer side edges) of the integrated circuit dice 502. The side-filling material is then cured to form solid side-filling layers 522. In the present embodiment, the side-filling material includes an epoxy based insulating material having filler content with a filler size of not more than 1 μm. The side-filling material is applied in a liquid form and is cured at 150° C. for 30 min to form the side-filling layers 522.

FIG. 5D shows a schematic 530 illustrating wafer-level molding to encapsulate the integrated circuit dice 502, the substrate 504 with the solder bumps 508 and the side-filling layers 522. The mold 532 includes a liquid epoxy encapsulant having a coefficient of thermal expansion from 5 ppm/° C. to 30 ppm/° C.

FIG. 5E shows a schematic 540 illustrating a reconstituted wafer 542 debonded from the mold plate 512. The reconstituted wafer 542 comprises the molded integrated circuit dice 502, the substrate 504 with the solder bumps 508 and the side-filling layers 522 formed in the mold 532. The schematic 540 shows a flipped reconstituted wafer 542 so that the top substrate surface and the active surfaces of the integrated circuit dice 502 are facing up and are left exposed (i.e. free from the mold 532). With the reconstituted wafer 542 being held together by the mold 532, a smooth and flat surface for forming a redistribution layer on the active surfaces of the integrated circuit dice 502 and the top substrate surface of the substrate 504 can be achieved, thereby providing a solution for existing challenges faced in RDL processing in wafer-level packages. This is shown in relation to FIG. 5F below.

FIG. 5F shows a schematic 550 illustrating a first redistribution layer (RDL) 552 formed on active surfaces of the integrated circuit dice 502 and the top substrate surface of the substrate 504. As shown in the schematic 550, the first RDL 552 is formed on portions, and not in entirety, of the active surfaces of the integrated circuit dice 502. In the present embodiment, the first RDL 552 is formed on the entire top substrate surface. Similar to the earlier embodiment, an even surface topology can be obtained using the molding process and the side-filling process by minimizing die protrusion between the integrated circuit dice 502. Similarly, therefore, a fine pitch first RDL 552 can be formed. The first RDL 552 in this case includes a pitch density/resolution of less than 2 μm per line or spacing.

FIG. 5G shows a schematic 560 illustrating a back-grinded bottom side of the reconstituted wafer 542 for exposing the solder bumps 508 formed on the substrate 504. In the present embodiment, the reconstituted wafer 542 is temporarily bonded to a transfer wafer for performing the back-grind process. The exposed solder bumps 508 can then be used to form electrical connections with the substrate 504 in subsequent integration steps.

FIG. 5H shows a schematic 570 illustrating lines 572 for dicing of the integrated circuit dice 502 to expose edge couplers. As shown in the schematic 570, the dicing is at the deep trenches formed in the integrated circuit dice 502. The exposed edge couplers can then be used to couple with external optical components optically.

FIG. 5I shows a schematic 580 illustrating an assembly of the wafer-level package to include other integrated circuit dice in the wafer-level package. In the present embodiment, instead of forming solder bumps on a second redistribution layer as shown in relation to FIG. 4I, new or secondary solder bumps 582 are formed directly on the solder bumps 508 for electrically contacting the substrate 504. To provide support during the assembly of the package on another substrate or a PCB, adhesive structures 584 can be formed on areas beneath the wafer-level package devoid of solder bumps 582. Other integrated circuit dice including an ASIC 586 and two electronic integrated circuit dices 588 (e.g. drivers or optical transimpedance amplifiers (TIA)) are formed or assembled on the first redistribution layer (RDL) 552. Laser diodes 590 are also provided and connected to the integrated circuit dice 502 (being PICs) and these can be coupled externally via the exposed edge couplers and optical fibers 592.

FIGS. 6 to 8 below show variations to the aforementioned wafer-level package structures 100, 130.

FIG. 6 shows a schematic of a cross-section of a wafer-level package 600 having dummy bumps 602 formed on areas beneath the wafer-level package 600 devoid of solder bumps 582 to provide support for the wafer-level package 600 during a subsequent assembly process, in place of the adhesive structures 584 as shown in relation to FIG. 5I. Similar features of the wafer-level package 600 are labelled using the same reference numerals and their descriptions are not repeated here for succinctness. The wafer-level package 600 with the solder bumps 582 and the dummy bumps 602 can be placed on a PCB 604 for subsequent integration.

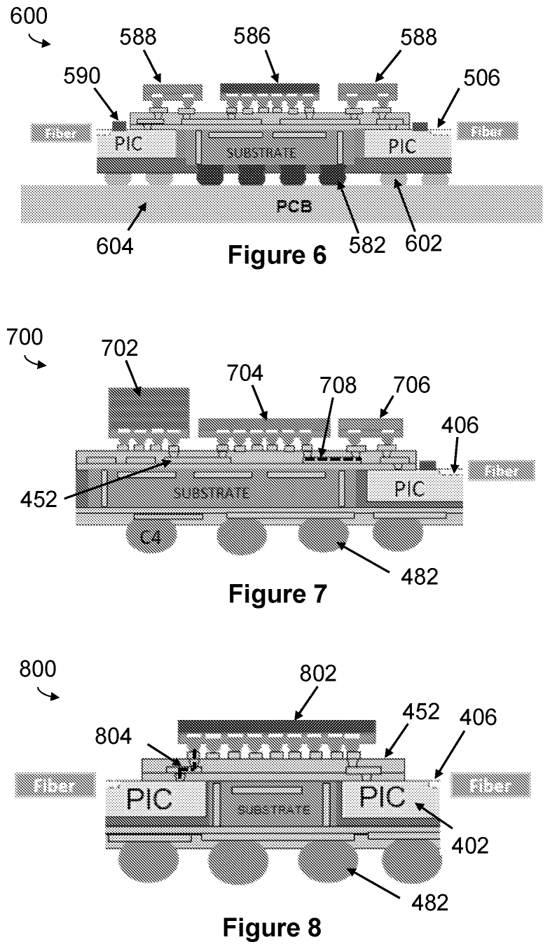

FIG. 7 shows a schematic of a cross-section of a wafer-level package 700 comprising a high bandwidth memory (HBM) 702, a graphics processing unit (GPU) 704 and a driver unit or TIA 706 formed on the first RDL 452 on a top substrate side in accordance with an embodiment. As discussed above, the first RDL 452 has a fine pitch of interconnects with a pitch having density/resolution of less than 2 μm per line or spacing enabled by the even surface topology achieved by the aforementioned method 400. This enables high density and high-bandwidth interconnects to be used at least between the HBM 702 and the GPU 704 for high bandwidth and fast speed applications. A short signal path 708 can also be formed between the GPU 704 and the driver unit 706 as shown in FIG. 7, where the GPU 704 and the driver unit 706 are kept on a same place (i.e. both the GPU 704 and the driver unit 706 are formed on a top surface of the first RDL 452).

FIG. 8 shows a schematic of a cross-section of a wafer-level package 800 comprising a switch component (e.g. ASIC) 802 formed on the first RDL on a top substrate side in accordance with an embodiment. The structure of the wafer-level package 800 enables three-dimensional (3D) integration where the switch component 802 is mounted directly above the integrated circuit dice 402 (e.g. PICs). In other words, the switch component 802 is configured to overlap with at least a portion of each of the integrated circuit dice 402, as shown in FIG. 8. This facilitates further shortening of an electrical link 804 between the switch component 802 and the integrated circuit dice 402 and in the present embodiment, the electrical link 804 is less than 100 μm. With this, the switch component 802 can drive the integrated circuit dice 402 without the need for driver EICs. This wafer-level package 800 is therefore able to scale to a 3D CPO.

FIG. 9 shows a schematic of a cross-section of the wafer-level package 900 of FIG. 1A to illustrate a shortened signal path 902 between the switch component 484 (e.g. ASIC) and the other integrated circuit dice 486 formed on the first redistribution layer (RDL) 452 on a top surface side of the wafer-level package 900. The wafer-level package 900 is placed on a PCB 904 as shown.

The present wafer-level package architecture shortens in-plane interconnects between (i) ASIC 484 and EIC 486, and (ii) between EIC 486 and PIC 488, in contrast to the prior art where high-density Interconnect (HDI) substrates and Through Silicon Vias (TSVs) or TSI are used. The use of HDI substrates, TSVs or TSI involves longer vertical and/or horizontal interconnects that cause high-speed signal loss. The wafer-level packages of the present disclosure therefore improve channel bandwidth and enable high-speed electrical links between package components.

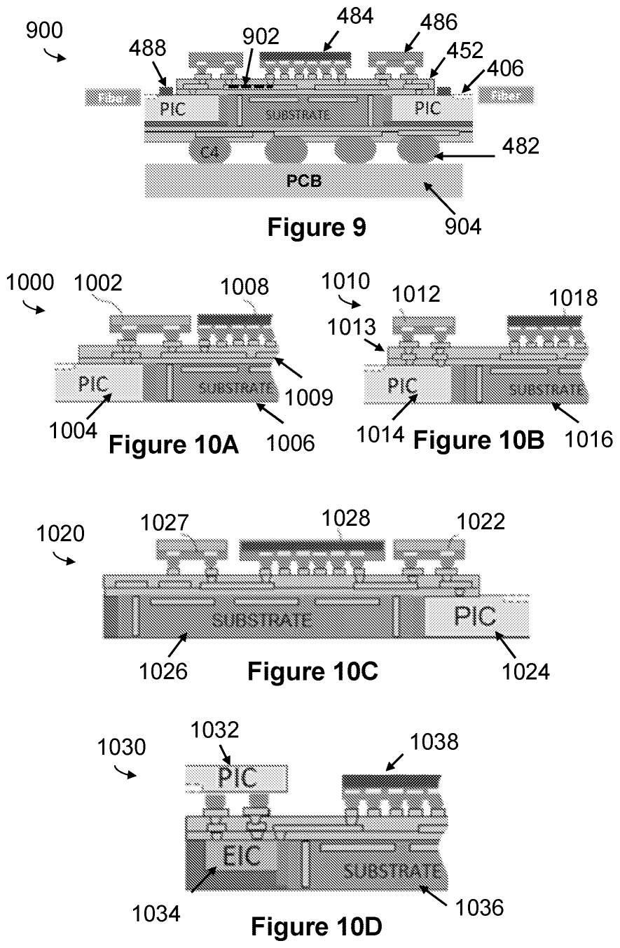

FIGS. 10A, 10B, 10C and 10D show schematics of a cross-section of a portion of a wafer-level package to illustrate various arrangements of a switch component and integrated circuit dice formed on a redistribution layer on a top surface side of the wafer-level package in accordance with embodiments. Only a section or a portion of a wafer-level package is shown for clarity. These architectures aid to facilitate shortened interconnects between various package components such as an ASIC (Switch/GPU), EICs (HBMs, Driver, TIA etc.), and PICs.

FIG. 10A shows a schematic of a cross-section of a wafer-level package 1000 having an electronic integrated circuit (EIC) 1002 overlapping an embedded photonic integrated circuit (PIC) 1004 and a substrate 1006 in accordance with an embodiment. A switch component or ASIC 1008 is provided on a RDL 1009, and is wholly above the substrate 1006. Similar to earlier embodiment, the PIC 1004 is provided adjacent or around the substrate 1006 and embedded within a mold that reinforces a mechanical integrity of the wafer-level package.

FIG. 10B shows a schematic of a cross-section of a wafer-level package 1010 having an EIC 1012 placed over a RDL 1013 and entirely above an embedded PIC 1014, in accordance with an embodiment. The EIC 1012 therefore overlaps with a portion of the embedded PIC 1014 but is itself wholly above the PIC 1014. Similar to the embodiment of FIG. 10A, a switch component or ASIC 1018 is provided on the RDL 1013 and is wholly above the substrate 1016.

FIG. 10C shows a schematic of a cross-section of a wafer-level package 1020 having an EIC 1022 overlapping an embedded photonic integrated circuit (PIC) 1024 and a substrate 1026 and another EIC 1027 placed entirely above the substrate 1026, in accordance with an embodiment. Similar to the embodiment of FIG. 10A, a switch component or an ASIC 1028 is provided wholly above the substrate 1026.

FIG. 10D shows a cross-section of a wafer-level package 1030 having a PIC 1032 placed entirely above an embedded EIC 1034, in accordance with an embodiment. Similar to the embodiment of FIG. 10A, a switch component or an ASIC 1038 is provided wholly above the substrate 1036.

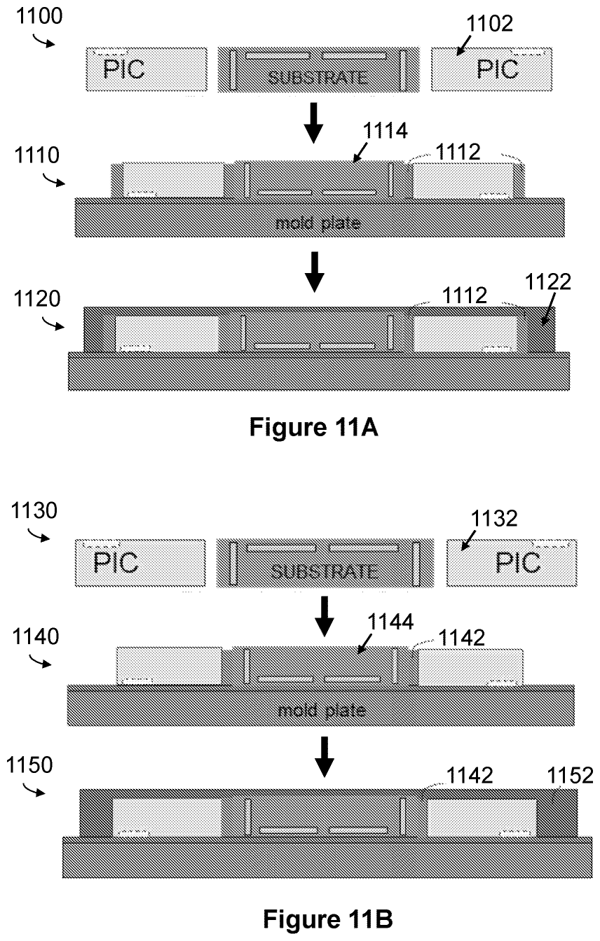

FIGS. 11A and 11B show schematics illustrating process flows in relation to formation of side-filling layers and subsequent molding of a wafer-level package in accordance with two embodiments. FIGS. 11A and 11B illustrate two embodiments having side-filling layers formed at one or more edge portions of embedded integrated circuit dice within a reconstituted molded wafer.

FIG. 11A shows schematics illustrating a process flow for forming side-fill layers at two or more sides of embedded integrated circuit dice 1102. The schematics 1100, 1110, 1120 are similar to process steps as illustrated by the schematics 400, 420 and 430 respectively, and therefore detail description in relation to these process steps are not repeated here for succinctness. In this embodiment, for forming the side-filling layers 1112, side-filling material is applied/provided both in gaps between the integrated circuit dice 1102 and the edge portions of the perimeter of the substrate 1114, and at other side edges (e.g. outer side edges) of the integrated circuit dice 1102. Wafer-level molding is then performed to encapsulate the integrated circuit dice 1102, the substrate 1114 and the side-filling layers 1112 using a mold 1122.

FIG. 11B shows schematics illustrating a process flow for forming side-fill layers only in gaps between a substrate and corresponding embedded integrated circuit dice. The schematics 1130, 1140, 1150 are again similar to process steps as illustrated by the schematics 400, 420 and 430 respectively, and therefore detail description in relation to these process steps are not repeated here for succinctness. In this embodiment, for formation of the side-filling layers 1142, side-filling material is applied/provided only in gaps between the integrated circuit dice 1132 and the edge portions of the perimeter of the substrate 1144. Wafer-level molding is then performed to encapsulate the integrated circuit dice 1132, the substrate 1144 and the side-filling layers 1142 using a mold 1152.

The side-filling layers 1112, 1142 formed prevent die-shift during the wafer over-molding process as illustrated in the schematics 1120, 1150.

FIG. 12 shows a schematic of a top view 1200 of the wafer-level package of FIG. 1A or FIG. 1B in accordance with an embodiment.

In the present embodiment as shown in relation to FIG. 12, multiple PICs 1202 are provided adjacent/around a perimeter of an embedded substrate 1204. The PICs 1202 and the embedded substrate 1204 are molded to form a reconstituted wafer. Part of a mold 1206 used in holding the PICs 1202 and the embedded substrate 1204 for forming the reconstituted wafer is shown in FIG. 12. The mold 1206 holds the PICs 1202 and the embedded substrate 1204 together so that the PICs 1202 and the embedded substrate 1204 do not move relative to one another and enables an even surface topography during formation of the wafer-level package. Further integrated circuit dice 1208 (e.g. EICs) are placed on a redistribution layer (c.f. 110, but not shown in the present FIG. 12). These integrated circuit dice 1208 can be provided entirely above the PICs 1202 or overlapping the embedded substrate 1204 and the PICs 1202 as shown in FIG. 12. A switch component 1210 (e.g. an ASIC) is provided entirely above the embedded substrate 1204. As discussed in relation to FIGS. 10A to 10D, other variations are possible. Laser diodes 1212 provided on the PICs 1202 are also shown, and these can be used to facilitate optical connections with one or more external optical components to the wafer-level package.

FIGS. 13A and 13B show schematics of a wafer-level package having side-filling layers in accordance with an embodiment.

FIG. 13A shows a schematic of a top view of a wafer 1302. As shown in this top view, a plurality of packages can be formed on wafer 1302 that can be processed at wafer-level. A zoom-in top view of one of the wafer-level packages 1304 is provided on the right of FIG. 13A. The wafer-level package 1304 shows a plurality of integrated circuit dice 1306 (e.g. PICs) provided adjacent to edges along a perimeter of an embedded substrate 1308. Although there are four integrated circuit dice 1306 provided adjacent each edge of the embedded substrate as shown in relation to FIG. 13A, it should be appreciated that a different number of integrate circuit dice 1306 (e.g. one, two, three, five etc.) can be provided in other embodiments. Side-filling layers 1310 are formed in gaps between the integrated circuit dice 1306 and edge portions of the perimeter of the substrate 1308, as well as at other side edges (e.g. outer side edges) of the integrated circuit dice 1306. The plurality of integrated circuit dice 1306, the embedded substrate 1308 and the side-filling layers 1310 are held together using a mold 1312 formed using a molding process step as exemplified in relation to FIGS. 4D and 5D.

FIG. 13B shows a schematic 1320 of a cross-section of the wafer-level package 1304. The cross-sectional view shows the filling of the side-filling layers 1310 in gaps between the integrated circuit dice 1306 and edge portions of the perimeter of the substrate 1308. Electrically conductive interconnects, both lateral/horizontal and vertical, embedded within the substrate 1308 are also shown.

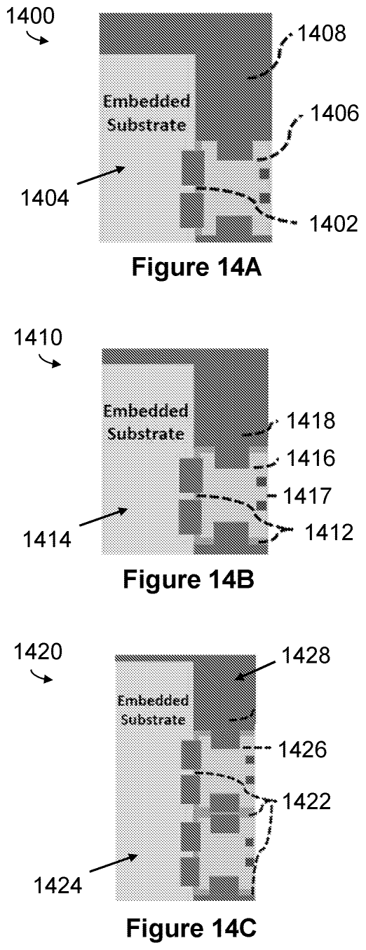

FIGS. 14A, 14B, 14C show schematics of top views of portions of wafer-level packages having different configurations of side-filling layers in accordance with embodiments.

FIG. 14A shows a schematic of a top view of a portion 1400 of a wafer-level package having a side-filling layer 1402 applied only at a gap between a substrate 1404 and an embedded integrated circuit die 1406.

FIG. 14B shows a schematic of a top view of a portion 1410 of a wafer-level package having side-filling layers 1412 applied around all sides of an embedded integrated circuit die 1416 inclusive of a gap between a substrate 1414 and the embedded integrated circuit die 1416. An optical facet 1417 is also shown in this diagram after dicing of the wafer-level package (e.g. as described in relation to FIGS. 4H and 5H).

FIG. 14C shows a schematic of a top view of a portion 1420 of a wafer-level package having side-filling layers 1422 applied around all sides of embedded integrated circuit dice 1426 inclusive of gaps between a substrate 1424 and the embedded integrated circuit dice 1426 and a gap between adjacent embedded integrated circuit dice 1426.

Side-filling layers can therefore be applied around one or more sides of one or more integrated circuit dice. This includes a space/gap between the one or more integrated circuit dice and an embedded substrate of a wafer-level package and/or between adjacent PICs. In a variation as shown in relation to FIG. 14A, it is also envisaged that side-filling layers are only formed at a space/gap between the one or more integrated circuit dice and the substrate. Also shown in relation to FIGS. 14A to 14C is that a mold 1408, 1418, 1428 is used to hold the side-filling layers 1402, 1412, 1422, the substrate 1404, 1414, 1424 and the integrated circuit dice 1406, 1416, 1426 provided around edges of a perimeter of the substrate 1404, 1414, 1424 together. The side-filling layers 1402, 1412, 1422 formed with gaps between the closely placed substrate 1404, 1414, 1424 and the integrated circuit dice 1406, 1416, 1426 (e.g. having a gap size of less than 10 μm) enables a flat and even top surface topography to be formed for these wafer-level packages. Further, the molded wafer-level package also minimizes die-shift and improves optical facet alignment across multiple embedded integrated circuit dice (e.g. PICs) during a subsequent dicing step. These contributed to the creation of fine pitch RDL metal interconnects for minimizing a footprint of the wafer-level package.

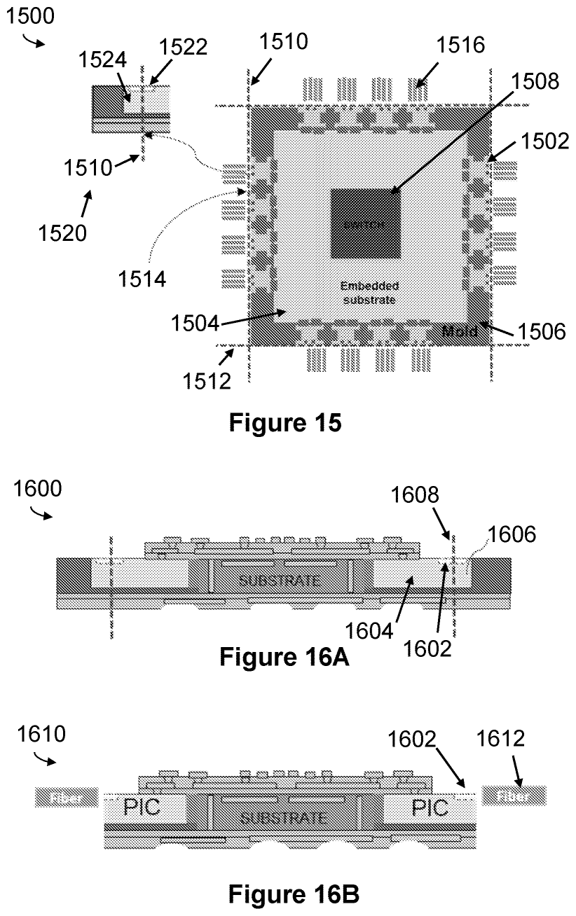

FIG. 15 shows a schematic of a top view and a cross-sectional view of a wafer-level package with outer edges of a plurality of embedded integrated circuit dice being diced to expose optical couplers in accordance with an embodiment. Similar to earlier embodiments, the plurality of embedded integrated circuit dice 1502 are formed around edges of a perimeter of a substrate 1504 and these are held together using a mold 1506. In the present embodiment, a switch component 1508 is provided wholly above the substrate 1504 over a redistribution layer (not shown) and it can be electrically connected to the plurality of embedded integrated circuit dice 1502 via the RDL and/or the substrate 1504.

In an embodiment, the plurality of embedded integrated circuit dice 1502 provided around edges of a perimeter of the substrate 1504 includes one or more photonic integrated circuit (PIC) dice. The one or more PIC dice can be with or without optical coupling structures formed at an outer edge of the integrated circuit die. In an embodiment, PICs with edge optical couplers (e.g. coupling inputs/outputs (I/Os)) are embedded inside a mold and at/around a perimeter of the wafer-level package, with these edge optical couplers being arranged to face outward towards perimeter edges of the wafer-level package. As shown in FIG. 15, the wafer-level package can be diced along the vertical dotted lines 1510 and/or the horizontal dotted lines 1512 to expose the edge optical couplers along the perimeter edges of the wafer-level package at once to form the optical facets 1514. Optical fiber or fiber arrays 1516 can then be coupled to these exposed edge optical couplers for operationally connecting the plurality of the embedded integrated circuit dice 1502 of the wafer-level package.

The cross-sectional view 1520 of the wafer-level package is shown on the left of FIG. 15, and it shows one of the edge optical couplers 1522 and a buffer region 1524 of the integrated circuit die 1502. The vertical dotted line 1510 for dicing the wafer-level package is also shown. The buffer region 1524 (e.g. a silicon buffer region) of the integrated circuit die 1502 which is used to protect the edge optical couplers 1522 during the molding process is removed by dicing through a deep trench after the wafer-package is assembled (see e.g. FIGS. 4I and 5I). The present wafer-level package architecture allows dicing of multiple buffer regions 1524 to expose multiple edge optical couplers 1522 at once and make sure that the optical facets 1514 formed for optical inputs/outputs (I/Os) are terminated at accurate positions to enable accurate optical coupling with external optical fibers 1516. As described in relation to embodiments above, side-filling layers can be formed in the wafer-level package to prevent die shift for enabling the dicing of all facets accurately while providing an even surface topography for subsequent RDL formation.

FIGS. 16A and 16B show schematics of cross-sections of a wafer-level package that is undergoing dicing of the outer edges of embedded integrated circuit dice in accordance with an embodiment. FIG. 16A shows a schematic of a cross-section of the wafer-level package 1600 being diced to expose an optical coupler 1602 of an embedded integrated circuit dice 1604. Similar to the cross-sectional view 1520 of the wafer-level package as shown on the left of FIG. 15, a buffer region 1606 is provided at the outermost edge of the embedded integrated circuit die 1602. A vertical dotted line 1608 indicating a position for dicing is also shown. FIG. 16B shows a schematic of a cross-section of a diced wafer-level package 1610 with an optical facet of the optical coupler 1602 being exposed and aligned to an external optical fiber 1612.

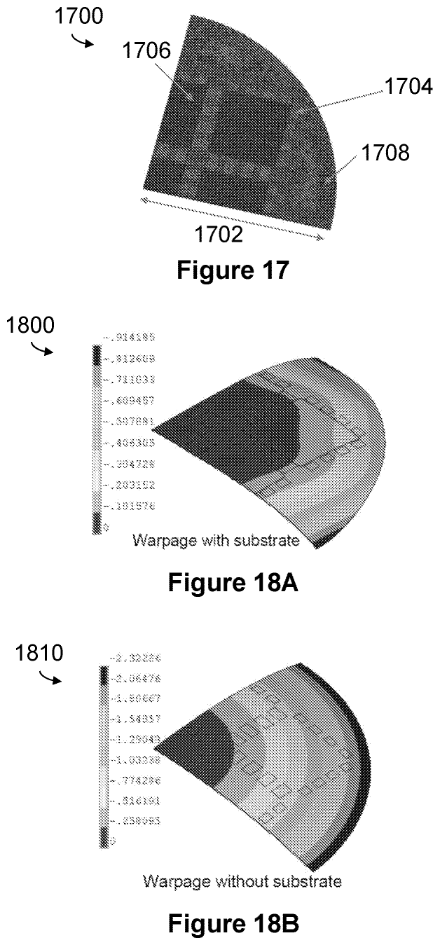

FIG. 17 shows a symmetric quarter model for use in evaluating warpage of a wafer with or without embedded substrates in accordance with an embodiment. The symmetric quarter model uses finite element analysis. In the present symmetric quarter model, a 300 mm diameter wafer is considered. A radius 1702 (or a length of a side of a quarter wafer) of the model used is therefore 150 mm. A plurality of integrated circuit dice 1704 formed around edges of a perimeter of a substrate 1706 is also shown. In the present example, the integrated circuit die 1704 includes a silicon (Si) photonic die having a size of 8 mm (length)×6 mm (width) and the substrate 1706 is of a square shape having a size of 55 mm (length)×55 mm (width). The integrated circuit dice 1704 and the substrate 1706 are held together by an epoxy mold compound (EMC) 1708. A total thickness for the wafer used in the symmetric quarter model is 860 μm.

FIGS. 18A and 18B show simulation results in relation to warpage of a wafer with or without embedded substrates using the symmetric quarter model of FIG. 17 in accordance with an embodiment.

FIG. 18A shows simulation results 1800 for warpage of the quarter wafer with embedded substrates and FIG. 18B shows simulation results 1810 for warpage of the quarter wafer without embedded substrates. The simulated warpage of the quarter wafer with a first dielectric coating with the embedded substrates is 915 μm while the simulated warpage with a first dielectric coating but without embedded substrates is 2.32 mm. It is therefore clear from the simulation results that a wafer without embedded substrates results in more warpage after wafer-level processing which will impede wafer-level integration.

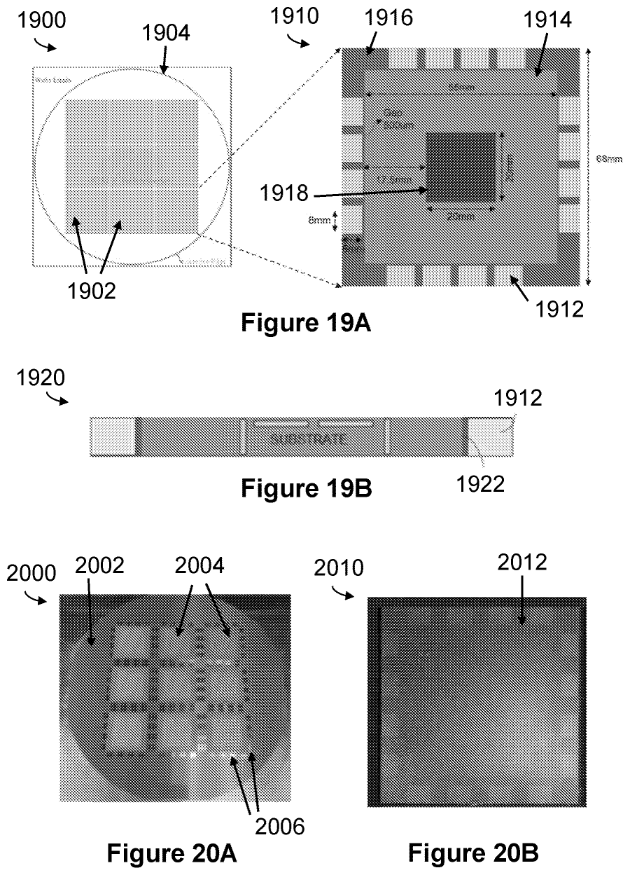

FIGS. 19A and 19B show schematics of wafer-level packages provided on a wafer for a feasibility experiment in accordance with an embodiment. The feasibility experiment is to investigate a feasibility of reconstituting very large wafer-level packages (e.g. more than 60 mm×60 mm in size) using substrates and integrated circuit dice (e.g. Si chips). Wafer warpage is also investigated after molding.

FIG. 19A shows schematics of a top view 1900 of wafer-level packages 1902 placement on a wafer 1904 and a top view of one of the wafer-level package 1910. The wafer-level package 1910 includes a plurality of integrated circuit dice 1912 formed around edges of a perimeter of a substrate 1914 and these are held together using a mold 1916. In the present embodiment, a switch component 1918 is provided wholly above the substrate 1914 over a redistribution layer (not shown) and it can be electrically connected to the plurality of embedded integrated circuit dice 1912 via the RDL and/or the substrate 1914. In the present experiment, square wafer-packages measuring 68 mm by 68 mm are formed on the wafer 1904. The substrate 1914 is also of a square shape having dimensions of 55 mm by 55 mm. The switch component 1918 is also of a square shape having dimensions of 20 mm by 20 mm, and is being placed centrally within the substrate 1914 (e.g. so that a distance between an edge of the substrate 1914 and an edge of the switch component 1918 is 17.5 mm). Each integrated circuit die 1912 has a dimension of 8 mm (length) by 6 mm (width) and is placed adjacent to a perimeter edge of the substrate 1914 with a gap between the perimeter edge of the substrate 1914 and an edge portion of the integrated circuit die 1912 being 500 μm. Although it is shown in this example that there were four embedded integrated circuit dice 1912 on each side of the substrate 1914, it will be appreciated that in other embodiments, a different number of embedded integrated circuit dice, for example one or two or three or five etc., can be provided on each side of the substrate.

FIG. 19B shows a schematic of a cross-section 1920 of the wafer-level package 1902 of FIG. 19A. Side-filling layers 1922 are used to fill gaps between the perimeter edge of the substrate 1914 and edge portions of the integrated circuit dice 1912 in the present experiment. The side-filling layers 1922 includes an epoxy based insulating material as previously discussed.

FIGS. 20A and 20B show photographs of wafer-level packages provided on a wafer for the feasibility experiment of FIGS. 20A and 20B. FIG. 20A shows a photograph of a placement of the wafer-level packages on the wafer 2002, where substrates 2004 and integrated circuit dice 2006 were picked and placed on the wafer 2002 for a subsequent molding process. FIG. 20B shows a photograph of a top view 2010 of one of the wafer-level packages as shown in FIG. 20A. The substrates 2004 and the integrated circuit dice 2006 were molded to form a reconstituted molded wafer. The experiment concluded that it is feasible to process large wafer-level packages (e.g. more than 60 mm×60 mm in size) on a wafer-level.

Embodiments of the present disclosure provide a wafer-level package and a method for forming the wafer-level package that enable heterogeneous integration of photonic integrated circuit dice and electronic integrated circuit dice using an embedded substrate. Wafer-level packages of the present embodiments use wafer-level co-packaged integration, rather than the assembly of discrete components as discussed in the prior art. This enables the wafer-level packages to be formed with a small form factor while minimizing production costs. Further, the wafer-level packages allow shorter electrical interconnects between various components (e.g. ASICs, EICs, PICs etc.), this reduces power loss/consumption and enables high speed/high bandwidth signal communications. By addressing issues related to power consumption and speed performance, reducing the form factor and optimizing cost, the wafer-level packages and the methods of the present disclosure can be applied to Hyperscale Data Centers (HDCs) and High-Performance Computing (HPC) applications.

Effects or advantages achieved by embodiments of the wafer-level packages and/or the method for forming the wafer-level packages include: (i) having an embedded substate in a wafer-level package to provide mechanical strength for large wafer-level processing; (ii) having fine pitch interconnects in wafer-level package redistribution layer(s) formed at the top and/or bottom of the wafer-level package which enables high density high bandwidth applications and avoids use of silicon interposer which minimizes production costs and package footprint; (iii) wafer-level packages having embedded integrated circuit dice (e.g. PICs) and flip-chip top integrated circuit dice (e.g. EICs) which can be interconnected using the fine pitch redistribution layers, thereby avoiding expensive and area-consuming TSV; (iv) use of side-filling layers to attach or anchor embedded PICs around the substrate inside the WLP to prevent die-shift during molding process, thereby enabling dicing of multiple Optical Engine (OE) structures to expose multiple couplers on multiple PIC for optical I/O) at the same time; (v) provide wafer-level design architectures that are cost effective in integrating components from different technologies and/or providing short in-plane interconnects to facilitate high-speed electrical links between high-speed ASIC (Switch/GPU), HBMs, electronic ICs (e.g. driver, transimpedance amplifier (TIA) etc.), and PICs; (vi) reducing manufacturing costs by wafer level integration, packing and testing; (vii) fan-out wafer level processing (FOWLP) enabling cost effective integration of heterogeneous technologies; and (viii) wafer-level packages as shown which are scalable to 3D CPOs and are applicable to future applications.

Alternative embodiments of the invention include: (i) one or more integrated circuit dice being provided adjacent to edge portions of the perimeter of the substrate; (ii) the substrate of a wafer-level package comprising an organic substrate; (iii) wafer-level packages formed without using side-filling layers; (iv) a wafer-level package comprising an organic substrate inside the mold with integrated circuit dice attached to one or more portions of the side edges around a perimeter of the organic substrate where each side edge around the perimeter of the organic substrate can be adjacent to one or more integrated circuit dice; (v) the one or more RDLs comprising electrically conductive interconnects being embedded horizontally and/or vertically within the one or more RDLs; (vi) the embedded integrated circuit dice (or the first integrated circuit dice) being positioned at less than 500 μm, less than 400 μm, less than 300 μm, less than 250 μm, less than 200 μm, or less than 100 μm from the edge portion of the perimeter of the substrate; (vii) the side-filling layer comprises an epoxy-based insulating material having filler content with a filler size of not more than 5 μm, not more than 4 μm, not more than 3 μm, not more than 2 μm, or not more than 1 μm; (viii) the mold comprises a liquid epoxy encapsulant having a coefficient of thermal expansion from 5 ppm/° C. to 30 ppm/° C., from 5 ppm/° C. to 20 ppm/° C., from 5 ppm/° C. to 10 ppm/° C. or from 1 ppm/° C. to 10 ppm/° C.; (ix) each of the embedded integrated circuit dice comprising a buffer region formed at the outer edge for protecting the one or more optical couplers from damage; (x) wafer-level process comprising reticle stitching during lithography; (xi) one or more embedded integrated circuit dice (i.e. integrated circuit dice with active surfaces in plane as a top substrate surface) comprising a photonic integrated circuit; (xii) one or more embedded integrated circuit dice (i.e. integrated circuit dice with active surfaces in plane as a top substrate surface) includes a photonic integrated circuit die with an optical coupling structure; (xiii) the first integrated circuit die comprises a passive chip that provides electrical connections between the second integrated circuit die and the third integrated circuit die and to the bottom substrate surface; and (xiv) the integrated circuit die 112 (or the second integrated circuit die) includes an application-specific integrated circuit (ASIC) or other appropriate integrated circuit (e.g. a HBM) dependent on an application of the wafer-level package.

Although only certain embodiments of the present invention have been described in detail, many variations are possible in accordance with the appended claims. For example, features described in relation to one embodiment may be incorporated into one or more other embodiments and vice versa.

1. A wafer-level package comprising:
a substrate having electrically conductive interconnects embedded within the substrate, the substrate having a top substrate surface and a bottom substrate surface opposite to the top substrate surface, the bottom substrate surface being adapted to be provided on a printed circuit board (PCB);
a first integrated circuit die having an active surface wherein the first integrated circuit die is provided adjacent to an edge portion of a perimeter of the substrate;
a mold adapted to hold the first integrated circuit die and the substrate so that the active surface of the first integrated circuit die is in a same plane as the top substrate surface;
a first redistribution layer having electrically conductive interconnects embedded within the first redistribution layer, the first redistribution layer being formed on the active surface of the first integrated circuit die and the top substrate surface; and
a second integrated circuit die provided on the first redistribution layer, the second integrated circuit die being electrically connected to the first integrated circuit die via the first redistribution layer.

2. The wafer-level package of claim 1, further comprising a third integrated circuit die provided on the first redistribution layer, the third integrated circuit die comprising a different type of integrated circuit to that of the first integrated circuit die and the second integrated circuit die.

3. The wafer-level package of claim 2, wherein the second integrated circuit die comprises an application-specific integrated circuit (ASIC) and wherein the first integrated circuit die comprises a photonic integrated circuit (PIC) and the third integrated circuit die comprises an electronic integrated circuit (EIC), or wherein the first integrated circuit die comprises an electronic integrated circuit (EIC) and the third integrated circuit die comprises a photonic integrated circuit (PIC), or wherein the first integrated circuit die comprises a passive chip that provides electrical connections between the second integrated circuit die and the third integrated circuit die and to the bottom substrate surface.

4. The wafer-level package of claim 2, wherein the third integrated circuit die is configured to overlap with a portion of the first integrated circuit die and a portion of the substrate, or wherein the third integrated circuit die is configured to overlap with only a portion of the first integrated circuit die.

5. The wafer-level package of claim 1, wherein the second integrated circuit die provided on the first redistribution layer is configured to overlap with a portion of the first integrated circuit die.

6. The wafer-level package of claim 1, further comprising a second redistribution layer having electrically conductive interconnects embedded within the second redistribution layer, the second redistribution layer being formed on a bottom side of the wafer-level package comprising the bottom substrate surface, or primary solder bumps formed on the bottom substrate surface.

7. The wafer-level package of claim 6, further comprising secondary solder bumps formed on the second redistribution layer or the primary solder bumps.

8. The wafer-level package of claim 1, further comprising a side-filling layer formed between the first integrated circuit die and the edge portion of the perimeter of the substrate to fill a gap between a side edge of the first integrated circuit die and the edge portion of the perimeter of the substrate.

9. The wafer-level package of claim 1, further comprising:
a plurality of integrated circuit dice provided adjacent to other edge portions of the perimeter of the substrate, wherein the mold is further adapted to hold the plurality of integrated circuit dice and the substrate so that an active surface of each of the plurality of integrated circuit dice is in the same plane as the top substrate surface.

10. The wafer-level package of claim 9, further comprising:
a plurality of side-filling layers formed between the first integrated circuit die and the edge portion of the perimeter of the substrate and between side edges of the plurality of integrated circuit dice and the other edge portions of the perimeter of the substrate,
wherein the mold is further adapted to hold the first integrated circuit die, the plurality of integrated circuit dice, the plurality of side-filling layers and the substrate so that an active surface of the first integrated circuit die and each of the plurality of integrated circuit dice are in the same plane as the top substrate surface.

11. The wafer-level package of claim 10, further comprising perimeter side-filling layers adapted to formed around other side edges of the first integrated circuit die and other side edges of the plurality of integrated circuit dice.

12. The wafer-level package of claim 11, wherein at least one of the perimeter side-filling layers is adapted to fill a gap between adjacent integrated circuit dice.

13. The wafer-level package of claim 9, wherein each of the first integrated circuit die and the plurality of integrated circuit dice comprises a photonic circuit having one or more optical couplers formed at an outer edge along a perimeter of the wafer-level package.

14. The wafer-level package of claim 13, wherein each of the first integrated circuit die and the plurality of integrated circuit dice further comprises a buffer region formed at the outer edge for protecting the one or more optical couplers from damage.

15. A method for forming a wafer-level package, the method comprising:
(i) providing a substrate having electrically conductive interconnects embedded within the substrate, the substrate having a top substrate surface and a bottom substrate surface opposite to the top substrate surface, the bottom substrate surface being adapted to be provided on a printed circuit board (PCB);
(ii) providing a first integrated circuit die having an active surface adjacent to an edge portion of a perimeter of the substrate;
(iii) forming a mold to hold the first integrated circuit die and the substrate so that the active surface of the first integrated circuit die is in a same plane as the top substrate surface;
(iv) forming a first redistribution layer having electrically conductive interconnects embedded within the first redistribution layer, the first redistribution layer being formed on the active surface of the first integrated circuit die and the top substrate surface; and
(v) providing a second integrated circuit die on the first redistribution layer, the second integrated circuit die being electrically connected to the first integrated circuit die via the first redistribution layer.

16. The method of any one of claim 15, further comprising:
providing a plurality of integrated circuit dice adjacent to other edge portions of the perimeter of the substrate,
wherein the step (iii) further comprises forming the mold to hold the plurality of integrated circuit dice and the substrate so that an active surface of each of the plurality of integrated circuit dice is in the same plane as the top substrate surface.

17. The method of claim 16, wherein each of the first integrated circuit die and the plurality of integrated circuit dice comprises a photonic circuit having one or more optical couplers formed at an outer edge along a perimeter of the wafer-level package.

18. The method of claim 17, further comprising: dicing the outer edge of each of the first integrated circuit die and the plurality of integrated circuit dice to expose the one or more optical couplers.

19. The method of claim 15, wherein the step (iii) further comprising:
placing the first integrated circuit die and the substrate on a mold plate, wherein the active surface of the first integrated circuit and the top substrate surface face the mold plate; and
forming the mold to hold the first integrated circuit die and the substrate on the mold plate.

20. The method of claim 19, further comprising: debonding the mold together with the first integrated circuit die and the substrate from the mold plate.
